(19) United States
(12) Patent Application Publication
(10) Pub. No.: US 2026/0282301 A1
(43) Pub. Date: Sep. 17, 2026

(54) THERMAL MANAGEMENT SYSTEMS AND METHODS FOR POWER DEVICES

(71) Applicants: Tau Motors, Inc., Redwood City, CA (US); The Trustees of Columbia University in the City of New York, New York, NY (US)

(72) Inventors: Walter Wesley Pennington, III, Portola Valley, CA (US); Michael Parker Owen, St. Augustine, FL (US); Gregory Gordon Stevenson, San Carlos, CA (US); Ethan Bagget Swint, Redwood City, CA (US); Matthew Jahnes, New York, NY (US); Matthias Preindl, New York, NY (US)

(21) Appl. No.: 18/873,869

(22) PCT Filed: Jun. 14, 2023
(86) PCT No.: PCT/US2023/025300

§ 371 Date: Dec. 11, 2024

Related U.S. Application Data
(60) Provisional application No. 63/351,893, filed on Jun. 14, 2022.

(51) Int. Cl. H05K 7/20; H02M 1/32; H02M 7/00

(52) U.S. Cl. CPC H05K 7/20927; H02M 1/327; H02M 7/003; H05K 7/20945

(57) ABSTRACT

Thermal management systems and methods are provided for managing thermal energy of a power converter and components thereof. In one example, a cooling jacket is coupled to a circuit board, where the cooling jacket has an inner surface that mimics a board surface profile formed by outward surfaces of a printed circuit board and electronic components thereon. Coolant fluid is provided through a coolant fluid pathway volume defined by the board surface profile and the inner surface of the cooling jacket. In another example, a cooling jacket covers an outward surface of an electronic component on a printed circuit board. The cooling jacket receives coolant fluid at an injection inlet and directs a jet of the coolant fluid toward the outward surface of the electronic component. The fluid exits the cooling jacket at an opening between the cooling jacket and a surface of the printed circuit board.

### CROSS-REFERENCE TO RELATED APPLICATIONS

This application claims priority to U.S. Provisional Application No. 63/351,893, filed on Jun. 14, 2022, which is hereby incorporated by reference in its entirety.

### STATEMENT REGARDING FEDERALLY SPONSORED RESEARCH

N/A

### TECHNICAL FIELD

Technology described herein relates generally to thermal management of power devices, and more particularly, to liquid cooling of power devices.

### BACKGROUND

Power electronics and power converters (collectively, power devices) of various types have been produced and used in many industries and contexts. Example power electronics include power switching elements such as insulated gate bipolar transistor (IGBT), metal-oxide-semiconductor field-effect transistor (MOSFET), gallium nitride (GaN) transistor switches, and the like. Example power converters include alternating current (AC) to direct current (DC) rectifiers, DC to AC inverters, and DC to DC converters. AC to DC rectifiers, also referred to as AC/DC rectifiers, convert AC power to DC power. DC to AC inverters, also referred to as DC/AC inverters, convert DC power to AC power. DC to DC converters, also referred to as DC/DC converters, convert an input DC power from a first DC voltage level to a second DC voltage level.

Power electronics may be included within power converters, as well as other electronics, to provide electronically controlled switching functionality within a circuit.

Power converters can be used for various purposes, such as rectifying AC power from an AC grid power source to DC power for charging a battery, or inverting DC power from a battery to AC power to drive a motor or supply AC power to an AC grid. Further, power converters can be used in various contexts, such as in or connected to an electric vehicle, an engine generator, solar panels, and the like.

### SUMMARY OF THE DISCLOSURE

Power electronics (e.g., IGBTs, MOSFETs, SiC or GaN switches, etc.) may be described in terms of power efficiency, power density, and cost, among other characteristics. Generally, it is desirable to have power electronics with higher power efficiency, higher power density, and lower cost. Similarly, power converters may be described in terms of power (conversion) efficiency, power density, and cost, among other characteristics. Generally, it is desirable to have power converters with higher power efficiency, higher power density, and lower cost. Disclosed herein are systems and methods related to power electronics and power converters that have increased power efficiency, increased power density, and/or reduced cost. In some of the embodiments described herein, the power devices include liquid cooling using a non-conductive fluid, such as non-conductive automotive transmission fluid (ATF) as the liquid medium, and direct jet impingement cooling.

In one embodiment, a thermal management system for a power converter is provided. The system comprises a printed circuit board having a first surface; a plurality of electronic components of the printed circuit board, each having an outward surface, the first surface and outward surfaces of the plurality of electronic components forming a board surface profile; a cooling jacket coupled to the printed circuit board, the cooling jacket having an inner surface, the inner surface having a surface profile that mimics the board surface profile; and a coolant fluid pathway volume defined by the board surface profile and the inner surface of the cooling jacket.

In one embodiment, a thermal management system for a power device is provided. The system comprises: a printed circuit board having a first surface; at least one electronic component of the printed circuit board, each of the at least one electronic component having an outward surface; and a cooling jacket. The cooling jacket includes a main portion covering the outward surface of the at least one electronic component, an injection inlet formed in the main portion, the injection inlet configured to receive a coolant fluid into the cooling jacket and to direct a jet of the coolant fluid toward the outward surface of the at least one electronic component, and an overhang portion overhanging a side surface of the at least one electronic component, the overhang portion including an opening between the cooling jacket and the first surface of the printed circuit board that provides an exit out of the cooling jacket for the coolant fluid directed toward the outward surface.

In one embodiment, a method of managing thermal energy is provided. The method comprises receiving a coolant fluid at an inlet of a coolant fluid pathway volume defined by an inner surface of a cooling jacket and a board surface profile. The board surface profile is formed by a first surface of a printed circuit board and outward surfaces of a plurality of electronic components of the printed circuit board. The inner surface has a surface profile that mimics the board surface profile. The method further comprises cooling a plurality of electronic components via the coolant fluid traveling through the coolant fluid pathway volume; and outputting the coolant fluid from an outlet of the coolant fluid pathway volume.

In one embodiment, a method of managing thermal energy is provided. The method comprises receiving a coolant fluid at an inlet formed in a main portion of cooling jacket, the main portion covering an outward surface of an electronic component on a first surface of a printed circuit board. The method further comprises directing, by a channel coupled to the inlet, a jet of the coolant fluid toward the outward surface of the electronic component; and expelling the coolant fluid out of the cooling jacket via an opening in an overhang portion of the cooling jacket, the opening being between the cooling jacket and the first surface of the printed circuit board.

The foregoing and other aspects and advantages of the present disclosure will appear from the following description. In the description, reference is made to the accompanying drawings that form a part hereof, and in which there is shown by way of illustration an embodiment or embodiments. These embodiments do not necessarily represent the full scope of the invention, however, and reference is therefore made to the claims and herein for interpreting the scope of the invention. Like reference numerals will be used to refer to like parts from Figure to Figure in the following description.

### BRIEF DESCRIPTION OF THE DRAWINGS

FIG. 1 illustrates a power converter system according to some embodiments.

FIG. 2 illustrates a power conversion circuit 200 according to some embodiments.

FIG. 3 illustrates a liquid cooling system 300 according to some embodiments.

FIGS. 4A-4C illustrates a thermal management system for a power device.

FIGS. 4D and 4E illustrates an exemplary coolant flow path.

FIG. 5 illustrates heat transfer coefficients for the thermal management system of FIGS. 4A-4C.

FIG. 6A illustrates a power converter system with liquid cooling.

FIG. 6B illustrates a jacket disposed on a top side of a printed circuit board (PCB) of FIG. 6A.

FIG. 6C illustrates jackets disposed on a top side and bottom side of the of FIG. 6A.

FIGS. 6D-E illustrate the power converter system of FIG. 6A with a jacket.

FIG. 7A illustrates a heat transfer of the PCB resulting from jacketed liquid cooling injected from a left side of the PCB.

FIG. 7B illustrates another orientation of a power converter system and its corresponding heat transfer profile.

FIG. 7C illustrates a graph depicting the relationship between pressure drop and flow rate of power converter systems with liquid cooling of FIGS. 7A and 7 B.

FIG. 8A illustrates a power converter system coupled to a plate.

FIG. 8B illustrates a graph depicting the relationship of liters per minute (LPM) and temperature with and without a heat spreader.

FIGS. 8C-8D illustrate another power converter system coupled to a plate with an overhang.

FIGS. 8E-8H illustrate another power converter system coupled to a plate with a flared inlet collector and side skirt.

FIG. 9A illustrates a portion of a PCB including three gapped inductors.

FIGS. 9B and 9C illustrate an inductor including a coil, winding, and

window.

FIG. 9D illustrates a boot jacketing an inductor.

FIG. 9E illustrates a coolant fluid flow diagram with respect to the boot jacketing the inductor of FIG. 9D.

FIGS. 9F, 9G, and 9H illustrate a clamshell boot for jacketing an inductor.

FIGS. 9I, 9J, and 9K illustrate a board-sealed boot for jacketing an inductor.

FIG. 10 illustrates heat transfer coefficients of the of the PCB of FIG. 9A.

FIG. 11 illustrates a control diagram of a power converter system according to some embodiments.

FIG. 12 illustrates graphs of temperature versus coolant flow rate.

### DETAILED DESCRIPTION

One or more embodiments are described and illustrated in the following description and accompanying drawings. These embodiments are not limited to the specific details provided herein and may be modified in various ways. Furthermore, other embodiments may exist that are not described herein. Also, functions performed by multiple components may be consolidated and performed by a single component. Similarly, the functions described herein as being performed by one component may be performed by multiple components in a distributed manner. Additionally, a component described as performing particular functionality may also perform additional functionality not described herein. For example, a device or structure that is “configured” in a certain way is configured in at least that way, but may also be configured in ways that are not listed.

As used in the present application, “non-transitory computer-readable medium” comprises all computer-readable media but does not consist of a transitory, propagating signal. Accordingly, non-transitory computer-readable medium may include, for example, a hard disk, a CD-ROM, an optical storage device, a magnetic storage device, a ROM (Read Only Memory), a RAM (Random Access Memory), register memory, a processor cache, or any combination thereof.

In addition, the phraseology and terminology used herein is for the purpose of description and should not be regarded as limiting. For example, the use of “comprising,” “including,” “containing,” “having,” and variations thereof herein is meant to encompass the items listed thereafter and equivalents thereof as well as additional items. Additionally, the terms “connected” and “coupled” are used broadly and encompass both direct and indirect connecting and coupling, and may refer to physical or electrical connections or couplings. Furthermore, the phase “and/or” used with two or more items is intended to cover the items individually and the items together. For example, a device comprising “a and/or b” is intended to cover any of: a device with “a” (and without “b”); a device with “b” (and without “a”); or a device with both “a” and “b.” As used herein, the terms “substantially,” “approximately,” “about,” and the like may refer to a value that is + or −1% (i.e., plus or minus 1 percent), + or −5%, + or −10% of the intended amount, value, angle, or other quantity.

A highly efficient power converter is able to convert power (e.g., AC to DC, DC to AC, and/or DC to DC) without significant losses in energy. A low efficiency power converter experiences higher losses in energy during the power conversion. Such energy losses may manifest as heat generated by the power converter while converting power, for example. Power efficiency for a power converter, inductor, or other electronic component may be expressed as a percentage between 0 and 100% and determined based on the power input to the component and the power output from the component using the equation:

$$Power Efficiency = \frac{Power Out}{Power In} .$$

A power converter with high power density has a high ratio of power output by the power converter compared to the physical space occupied by the power converter. The power density can be calculated using the equation:

$$Power Density = \frac{Power Out}{Volume of Power Converter} .$$

Applications, particularly advanced or modern applications, that include power electronics (e.g., IGBT, MOSFET, and GAN switches, etc.) power converters (e.g., transformers, converters, inverters, etc.), or passive power components (e.g., inductors, capacitors, etc.) benefit from an increase to the power density (or power per unit volume- or mass) of the power electronics and power converters. Effective thermal management is a tool to increase the power density of such systems where, by definition, more power is pushed through a given (or smaller) area. Further, effective thermal management can provide a method to increase the lifetime of such power devices, converters, or components. Traditional methods of thermal management include air cooling, convective heat transfer using heat sinks, and indirect convection using coolants. These solutions, however, often fall short as their thermal management capability is limited and prevents substantial increases in power density for existing power electronic and power converters. Disclosed herein are devices and methods for providing an increase in power density of such systems, offering an increase in power within the context of traditional devices beyond what is otherwise achievable.

Further, traditional systems that may utilize direct or indirect liquid cooling methods focus on increasing the flow rate of the liquid, which is often prohibitive (e.g., due to the increased pressures required) and limits the efficiency and/or viability of the method altogether—not withstanding thermal limitations further discussed herein. Disclosed herein are devices and methods that overcome these shortcomings and enable improved power densities while maintaining overall system efficiency.

In some embodiments, a direct liquid cooling strategy is disclosed for higher efficiency and higher power operation of power electronics and power conversion devices using a novel mechanical design, as well as a control of the system that allow for enhanced performance in terms of both efficiency of operation and operating envelope (e.g., operation within transient and steady state thermal limits). These features enable high power density for their systems. Further, counter to manufacturer limits and specification, the devices and methods included herein enable devices to effectively exceed their data sheet values for rated current and decrease ohmic losses for devices under operation. Moreover, the lifetime of such devices can be benefited with a reduction in degradation resulting from thermal cycles. The need for such enhanced operation can be critical for high power density power converters and devices, which—in particular—have high current loading requirements, variable power requirements (e.g., wide loading requirements such as traction applications, with a high peak load and low partial load), and/or high continuous operating conditions. The disclosed thermal management systems are carefully designed and controlled to prevent both thermal breakdown of the coolant and thermal runaway of the system.

In some embodiments, the thermal management system for power electronics or power conversion devices provides an impinged fluid (coolant, e.g., oil or automatic transmission fluid, or the like) stream in operation onto the device(s) with a cooling device that interfaces with the power electronics or power conversion devices, which allows—for a given flow rate of fluid—the system to keep the fluid flow space narrow such that the fluid flow velocity and heat transfer coefficient (HTC) are both elevated. This cooling device, in turn, enables the surface area to volume ratio of the cooling region to become larger and use the fluid more effectively. Because the velocity is enforced to be relatively high, the residence time of the fluid remains relatively low. Thus, the absolute temperature rise of the coolant also remains low and prevents thermal breakdown of the fluid, which is otherwise often observed when attempting to interface a device directly with a fluid either through spray or submerged methods. Further, in some examples provided herein, the fluid may be directed at the top and bottom of a device under cooling, or both, which is atypical of traditional cooling methods. Additionally, in some examples provided herein, the device ensures that the entire heat rejecting surface of the power electronics or power conversion devices under cooling remain fully wetted by the coolant, maximizing heat rejection.

Disclosed herein are thermal management systems and methods for power electronics and power converters that can provide power switching and power conversion with increased power efficiency, increased power density, and/or reduced cost. In some of the embodiments described herein, the power electronics and power converters include thermal management systems and methods with liquid cooling using a non-conductive fluid, such as non-conductive automotive transmission fluid (ATF) or such other conductive dielectric as the liquid medium, and with direct jet impingement cooling.

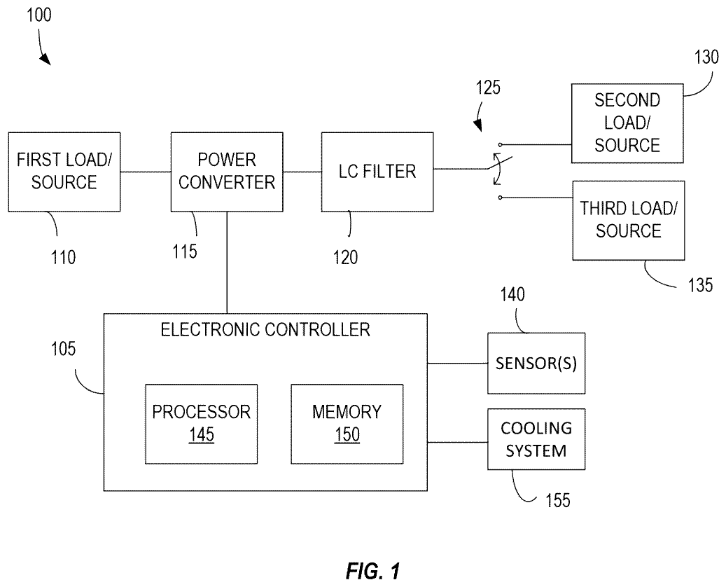

FIG. 1 illustrates a power converter system 100, according to some embodiments. The power converter system 100 includes an electronic controller 105, a first load/source 110, a power converter 115, an LC filter 120, a contactor 125, a second source/load 130, a third source/load 135, one or more sensors 140, and a cooling system 155.

In operation, generally, the electronic controller 105 controls power switching elements of the power converter 115 with a high frequency control signal to convert power from: (i) the first load/source 110 functioning as a source to the second source/load 130 or the third source/load 135 (depending on the state of the contactor 125) functioning as a load, or (ii) the second source/load 130 or the third source/load 135 (depending on the state of the contactor 125) functioning as a source to the first load/source 110 functioning as a load. Accordingly, when the first load/source 110 is functioning as a source for the power converter 115, the second source/load 130 (or third source/load 135, depending on the state of the contactor 125) is functioning as a load for the power converter 115. Conversely, when the first load/source 110 is functioning as a load for the power converter 115, the second source/load 130 (or third source/load 135, depending on the state of the contactor 125) is functioning as a source for the power converter 115.

The first load/source 110 may be a direct power (DC) load, a DC source, or both a DC load and DC source (i.e., functioning as DC source in some instances and as a DC load in other instances, depending on the mode of the power converter 115). In some examples, the first load/source 110 is a battery. The second source/load 130 and the third source/load 135 may be a DC load, a DC source, both a DC load and DC source, an AC load, an AC source, or both an AC load and AC source (i.e., functioning as an AC source in some instances and as an AC load in other instances, depending on the mode of the power converter 115). In some examples, the second source/load 130 is an electric motor and the third source/load 135 is an AC generator or AC power supply grid. In some examples, the second source/load 130 and the third source/load 135 are both DC batteries. In some examples of the system 100, the second source/load 130 is connected to the LC filter 120 without the intermediate contactor 125, and the contactor 125 and the third source/load 135 are not present in the system 100.

The first load/source 110 is coupled to the power converter 115 at a first side of the power converter 115, and the second source/load 130 (or the third source load 135, depending on the state of the contactor 125) is coupled to the power converter 115 at a second side of the power converter 115. The first side may also be referred to as an input side or an output side of the power converter 115, depending on the mode of the power converter, or as a DC side of the power converter 115. The second side may also be referred to as an input side or an output side of the power converter, depending on the mode of the power converter, or as a DC side or an AC side of the power converter 115, depending on the power type of the second and/or third source/load 130, 135. In some embodiments, the second side of the power converter 115 may be an AC side having single phase AC power, three-phase AC power, or AC power with another number of phases.

In some embodiments, the power converter 115 operates with a high DC voltage level. For example, in operation, the DC side of the power converter 115 has a DC voltage (e.g., across input terminals of the power converter 115) of at least 200 V, at least 600 V, at least 800 V, at least 1000 V, at least 1200 V, between 200 V and 1200 V, between 600 V and 1200 V, between 800 V and 1200 V, or another range. Such high DC voltage levels may be desirable in some contexts, such as some electric vehicles. For example, some current electric vehicles (e.g., passenger vehicles and hybrid electric vehicles) operate with a DC bus voltage of between about 200 V and 400 V. This DC bus voltage for passenger electric vehicle may increase in the future. Further, some current electric vehicles (e.g., class 4-8, off-road, or otherwise larger electric vehicles) can operate with a DC bus voltage of more than 1000 V. However, high DC voltage levels may introduce challenges into a typical power converter system, such as an increase in heat generation, an increase in component size and/or expense to handle the increased heat generated in operation, and/or limits to operation due to heat limits for circuit components. Embodiments described herein provide improved cooling of the power converter system to mitigate or eliminate one or more of these challenges, ultimately providing power converter systems with reduced power density, reduced cost, and/or improved efficiency.

The sensor(s) 140 include, for example, one or more current sensors, one or more a voltage sensors, and/or one or more temperature sensors. For example, the sensor(s) 140 may include a respective current sensor and/or voltage sensor to monitor a current and/or voltage of each phase of one or more of the first/load source 110, the second source/load 130, the third source/load 135, the LC filter 120, or the power converter 115. For example, when the LC filter 120 is a three-phase LC filter, the sensors 140 may include at least three current sensors, one for sensing current at each phase of a three phase LC filter 120. In some embodiments, additional or fewer sensors 140 are included in the system 100. For example, the sensors 140 may also include one or more vibration sensors, temperature sensors, and the like. In some examples, the controller 105 infers a characteristic (e.g., current or voltage) of the power converter 114, rather than directly sensing the characteristic. In some examples, the sensor(s) 140 include one or more temperature sensors to sense the temperature of the system 100 or components thereof (e.g., the power converter 115, the electronic controller 105, and/or the LC filter 120), and/or one or more temperature sensors to sense ambient temperature in the environment of the system 100 or components thereof (e.g., the power converter 115, the electronic controller 105, and/or the LC filter 120). The temperature sensor(s) may output an indication of the sensed temperature to the electronic controller 105, which may be used as a basis on which the electronic controller 105 controls the cooling system 155.

The electronic controller 105 includes an electronic processor 145 and a memory 150. The memory 150 includes one or more of a read only memory (ROM), random access memory (RAM), or other non-transitory computer-readable media. The electronic processor 145 is configured to, among other things, receive instructions and data from the memory 150 and execute the instructions to, for example, carry out the functionality of the controller 105 described herein. For example, the memory 150 includes control software. As described in further detail below, generally, the electronic processor 145 may be configured to execute the control software to monitor the system 100 including the power converter 115 (e.g., based on sensor data from the sensor(s) 140), receive commands (e.g., via an input/output interface), and to drive the power converter 115 (e.g., in accordance with sensor data and/or the commands). In some embodiments, instead of or in addition to executing software from the memory 150 to carry out the functionality of the controller 105 described herein, the electronic processor 145 includes one or more hardware circuit elements configured to perform some or all of this functionality.

Although the controller 105, the electronic processor 145, and the memory 150 are each illustrated as a respective, single unit, in some embodiments, one or more of these components is a distributed component. For example, in some embodiments, the electronic processor 145 includes one or more microprocessors and/or hardware circuit elements. In some examples, the electronic controller 105, electronic processor 145, and/or memory are implemented as a microcontroller, a field programmable gate array (FPGA), or an applicant specific integrated circuit (ASIC).

The cooling system 155 is in communication with electronic controller 105 and is controllable to provide cooling to components of the system 100, such as to the power converter 115 (and its power switching elements) and/or the LC filter 120. In some examples, the electronic controller 105 controls the cooling system 155 based on characteristics of the system 100, as described further below. For example, generally, the electronic controller 105 may increase a cooling action of the cooling system 155 as a temperature of the system 100 rises and decrease the cooling action of the cooling system 155 as the temperature of the system 100 decreases. In some examples, to control the cooling system 155 based on temperature as described, the electronic controller 105 may determine the temperature of the system 100 (or components thereof) based on sensor data received from one or more of the sensor(s) 140 (e.g., a temperature sensor or current sensor where current may be proportional to temperature) or based on inference from the manner in which the system 100 is being operated (e.g., may infer higher temperature from higher switching frequency and vice-versa). In some examples, as described in further detail below, the cooling system 155 may include a liquid coolant with direct jet impingement of components of the system 100 to be cooled.

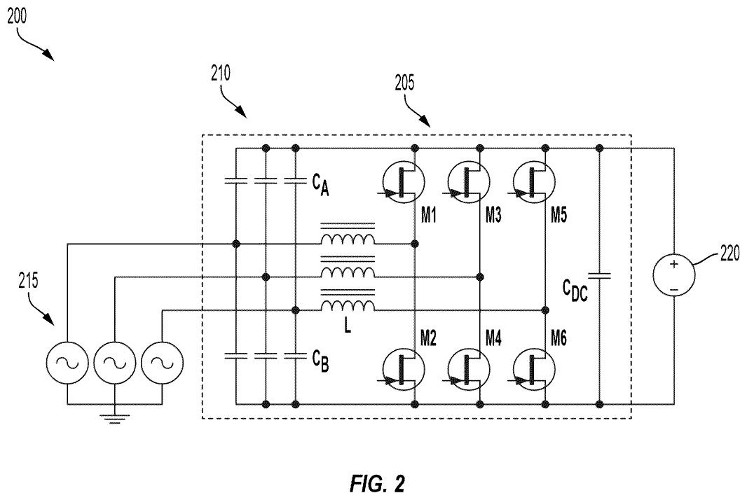

FIG. 2 illustrates a power conversion circuit 200 according to some embodiments. The circuit 200 includes a power converter 205, LC filter 210, AC grid 215, and DC battery 220. The power converter circuit 200 provides a circuit topology usable in some examples of the power conversion system 100. For example, the power converter 205 is an example of the power converter 115 of FIG. 1 and includes six MOSFETs (M1-M6) as power electronics (also referred to as power switching elements). In operation, an electronic controller (e.g., electronic controller 105 of FIG. 1) provides a switching control signal to each of the power switching elements of the power converter 205. The switching control signals may be pulse width modified (PWM) control signals having a frequency and duty cycle set by the electronic controller to control the power conversion of the power converter 205. The electronic controller may generate the switching control signals based on sensor data received from the sensor(s) 140 (e.g., based on current and/or voltage measurements) using, for example, known control techniques.

Additionally, the LC filter 210 is an example of the LC filter 120, the AC grid 215 is an example of the first load/source 110, and the DC battery 220 is an example of the second source/load 130. In this example, a third source/load 135 and contactor 125 are not included; however, in some embodiments, these elements are included in the circuit 200. A cooling system and controller, such as the cooling system 155 and the controller 105 of FIG. 1, are not illustrated in FIG. 2, but may be present as provided with respect to the system 100 of FIG. 1 and as provided throughout this disclosure. FIG. 2 provides one particular arrangement of components; however, in other examples, the power converter 205 includes another converter topology, a different number of power electronics, and/or a different type of power electronics or semiconductor (e.g., IGBT, GaN, etc.)

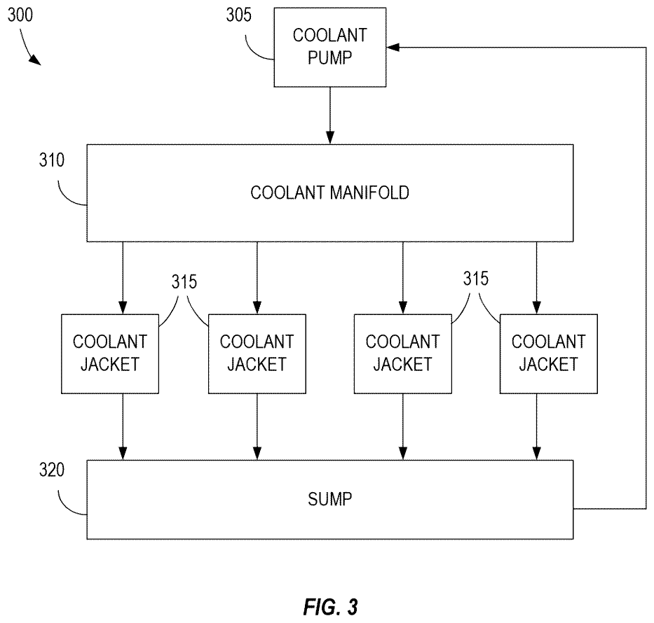

FIG. 3 illustrates a liquid cooling system 300 according to some embodiments. The liquid cooling system 300 is an example of a cooling system that may be used with the system 100 of FIG. 1 (i.e., serving as the cooling system 155) and with the circuit 200 of FIG. 2. The liquid cooling system 300 includes a coolant pump 305, a coolant manifold 310, cooling jackets 315 (also referred to as coolant jacket 315), and a sump 320. The cooling system 300 may also be referred to as a thermal management system 300.

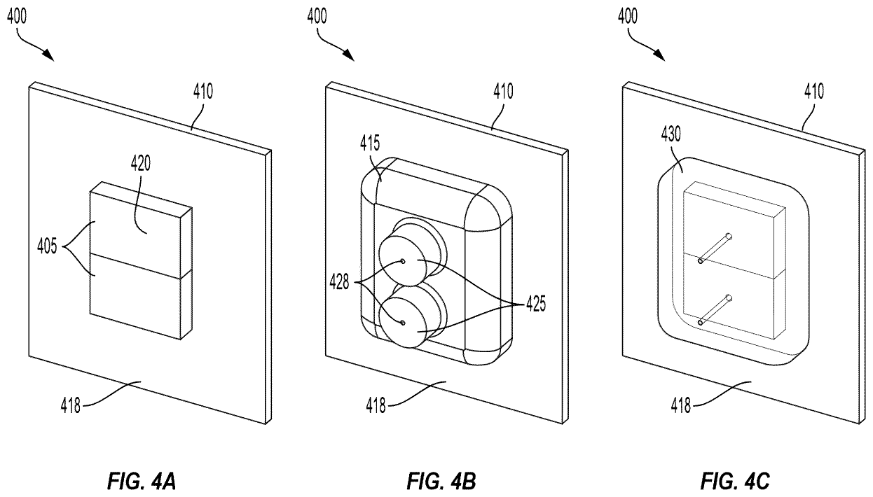

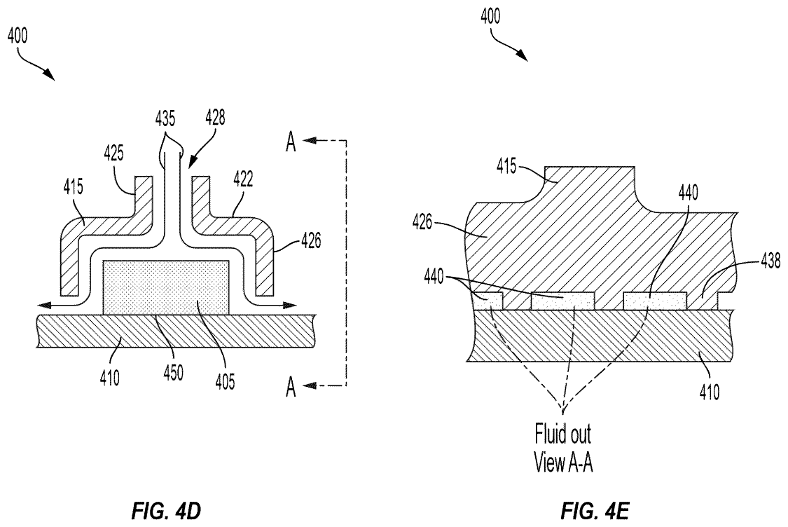

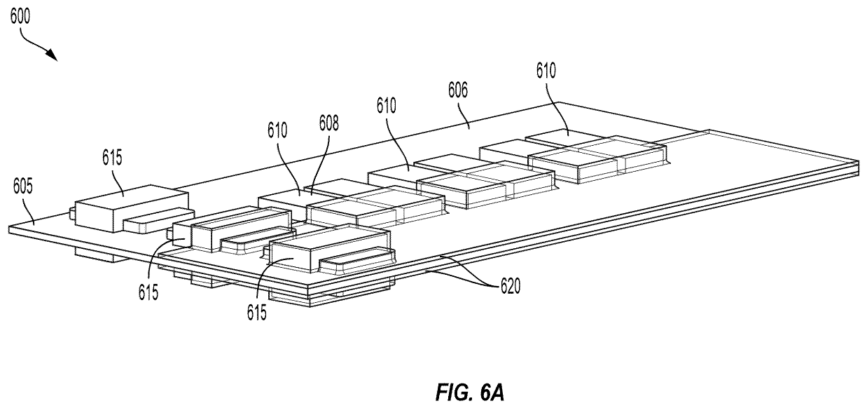

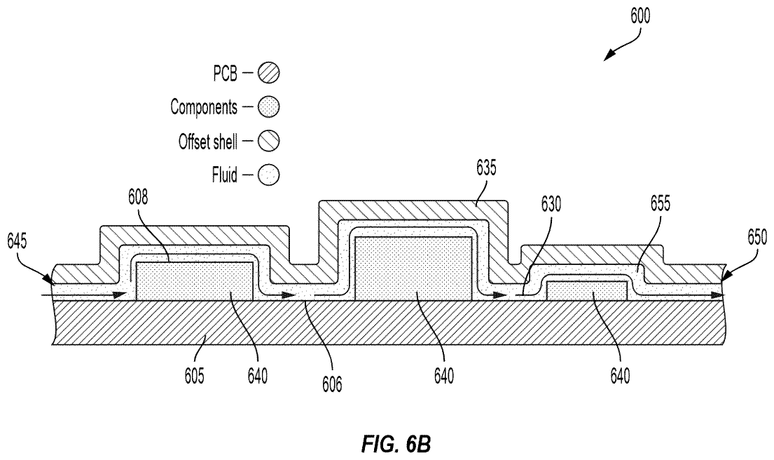

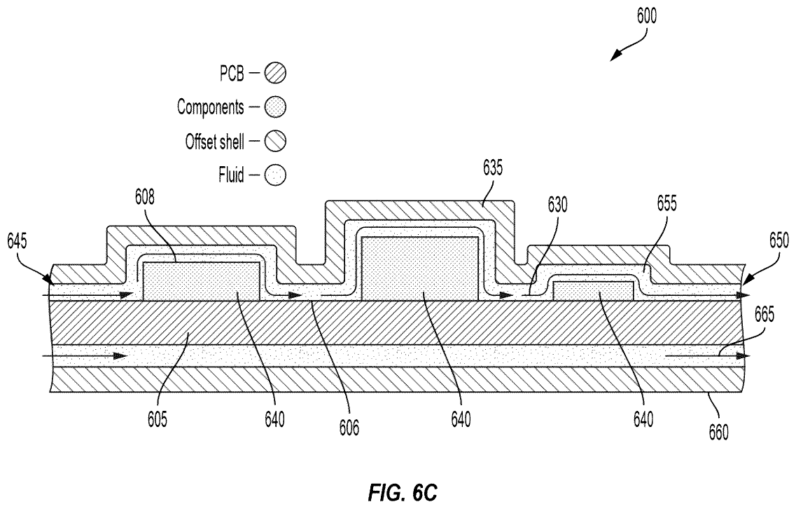

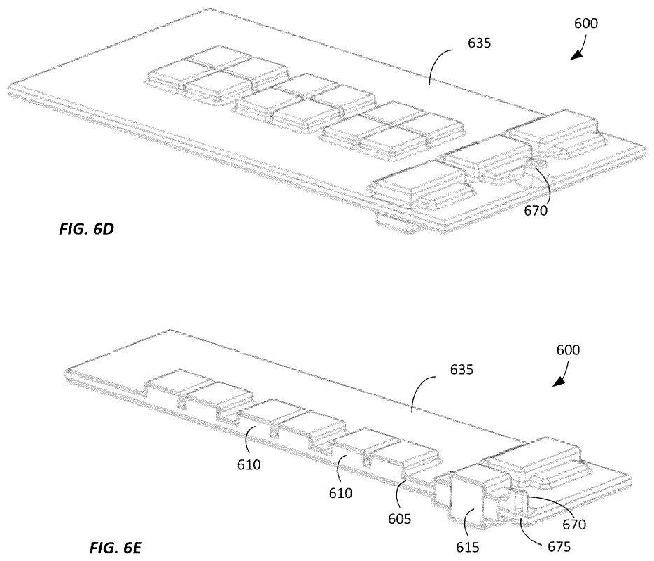

The coolant pump 305 is configured to pump liquid coolant to flow through the coolant manifold 310 and, ultimately, the cooling jackets 315. The sump 320 collects the pumped liquid coolant after flowing through the cooling jackets 315 and provides a return path for the liquid coolant back to the coolant pump 305. In some embodiments, a coolant manifold 310 is not provided and the coolant pump 305 pumps liquid coolant directly to the cooling jackets 315. In some examples, a single cooling jacket 315 may be provided for a printed circuit board as a whole (see, e.g., FIGS. 6A-B) or for an individual component or components on a circuit board. In other examples, a system may include multiple cooling jackets 315 to cool respective components on the same printed circuit board or both sides of a printed circuit board. For example, each cooling jacket 315 may be associated with a circuit element or elements on a circuit board to be cooled with direct jet impingement of the liquid coolant (see, e.g., FIGS. 4A-C). In either case, the liquid coolant may be a nonconductive liquid cooling medium, such as a nonconductive automotive transmission fluid (ATF).

The coolant pump 305 may be controlled (e.g., to start pumping, to stop pumping, and/or to pump at a desired or set rate) by a controller, such as the controller 105. In some examples, when the cooling system 300 of FIG. 3 is used in the system 100 as the cooling system 155 (see FIG. 1), the electronic controller 105 controls the cooling system 300 and, more particularly, the coolant pump 305 based on characteristics of the system 100 (e.g., sensed with one or more of the sensor(s) 140), such as sensed temperature of the system 100 or components thereof, sensed ambient temperature in the environment of the system 100 or components thereof, current input level, current output level, voltage input level, voltage output level, power input level, power output level, switching frequency of the power converter 115, and/or a duty cycle of a control signal of the power converter 115. Generally, the controller 105 may proportionally increase the cooling action of (or heat dissipation provided by) the cooling system 300 as the controller 105 determines that characteristics of the system 100 indicate an actual or likely increase in temperature of the system 100 (or components thereof). Conversely, the controller 105 may proportionally decrease the cooling action of (or heat dissipation provided by) the cooling system 300 as the controller 105 determines that characteristics of the system 100 indicate an actual or likely decrease in temperature of the system 100 (or components thereof).

To increase the cooling action of the cooling system 300, the controller 105 may provide a control signal (also referred to as a command signal) to the coolant pump 305 to increase the pumping rate of the coolant pump 305 and, thus, the coolant flow rate through the coolant system 300. Similarly, to decrease the cooling action, the controller 105 may provide a control signal to the coolant pump 305 to decrease the pumping rate of the coolant pump 305 and, thus, the coolant flow rate through the coolant system 300.

The thermal management systems and methods provided herein may be used at a system level, or a local module or device level.

In some embodiments of the thermal management systems and methods provided at the local device level, the system and methods take advantage of the local maximum in heat transfer at a location of fluid jet impingement. Hence, these systems and methods may cool individual dissipating components directly through the device and its operation. The heat-rejecting surface of components, such as FETs, diodes, or resistors, is targeted for the cooling capability. The surface of the thermal management device can maintain high bulk velocities over the entire heat rejection surface and ensure that the entire surface of the device under cooling remains fully wetted. The injection point may be located directly over the junction to maximize cooling efficiency. Additionally, locally pressurizing the fluid may squeeze the coolant equally into all available spaces. That is, the coolant does not have a tendency to bypass dissipating components.

FIGS. 4A-4C illustrate a thermal management system for a power device and, more particularly, a direct jet impingement system 400. The system 400 includes two neighboring or adjacent heat generating electronic components 405 (e.g., FETs) on a printed circuit board (PCB) 410 (see FIG. 4A) and a shared cooling jacket 415 (see FIG. 4B). The system 400 may be used in conjunction with the cooling system 300 (and, thus, the system 100). For example, the cooling jacket 415 is an example of one of the cooling jackets 315 of FIG. 3. In some examples, the system 300 of FIG. 3 may implement each cooling jacket 315 as one of the cooling jackets 415, thus providing a cooling system with a set of cooling jackets 415 that cool respective components 405 with pressurized liquid coolant via direct jet impingement. That is, the cooling system 400 directs fluid through an opening in the cooling jackets 415 directly onto the two neighboring dissipating components 405 (e.g., FETS). In some examples, the cooling jacket 415 is tightly fitted to the electronic components 405, and the injection inlets are thus positioned a short or tight distance from the target surface to be cooled. As used herein, a “tight” clearance, fit, or distance may refer to a distance (or space between components) of less than about 1 millimeter (mm), less than 0.75 mm, less than 0.5 mm, less than 0.3 mm, between 0.2 and 1 mm, between 0.2 and 0.75 mm, between 0.2 and 0.5 mm, about 0.25 mm, about 0.5 mm, about 0.75 mm, or about 1 mm. The particular distance of the tight clearance or fit may vary depending on the heat transfer coefficients desired to reject a target amount of heat and the available flow rate and back pressure limitations for a given design. The outlet around the perimeter of the device is restricted to ensure the cavity of the cooling device stays flooded and maintains flow on the target surface such that it is fully wetted with a high local velocity of fluid.

The PCB 410 includes a first surface 418 on which the electronic components 405 are mounted. The electronic components 405 include a mounting surface (see surface 450 in FIG. 4D) via which the electronic components 405 are mounted to the first surface 418 of the PCB 410. The electronic components 405 further include an outward surface 420 opposite the mounting surface.

The system 400 takes advantage of the local maximum in heat transfer at the location of jet impingement by cooling individual dissipating components via direct jet impingement of liquid coolant through the local cooling jacket 415. With reference to FIGS. 4B and 4D, the cooling jacket 415 includes a main portion 422 covering the outward surface of the electronic components 405, injection inlets 425 formed in the main portion, and an overhang portion 426. As illustrated, the cooling jacket 415 may have a curved transition from the main portion 422 to the overhang portion 426. The injection inlets 425, also referred to as fluid input connectors, are configured to receive the liquid coolant flow. As illustrated, the injection inlets 425 may be generally cylindrical. The injection inlets 425 include a fluid channel or path 428 connecting the external coolant source flow (e.g., provided by a tubing connected to a manifold or pump) to the heat generating components that are cooled. That is, the liquid coolant flows through the fluid channel or path of the injection inlets 425 and is output from the fluid channel or path 428 towards the heat generating components 405 to provide the direct jet impingement thereof. In some examples, the channel or path 428 of the injection inlets 425 through the jacket 415 is equal to approximately 10 times the diameter of the inlet. In some examples, the channel or path 428 has a diameter that is substantially smaller (e.g., three, four, five, or more times smaller) than the diameter of a supply tube providing the liquid coolant to the cooling jacket 415, which may match the diameter of the inlets 425 for a snug fit. In other words, the cross-sectional area of the channel or path 428 is smaller than the cross-sectional area of the supply tube, where the cross-sectional areas refer to the surface areas of imaginary two-dimensional planes that are perpendicular to the flow of the coolant fluid. Accordingly, the channel or path 428 narrows the fluid flow space such that the fluid flow velocity through the channel 428 is increased (relative to the velocity of the fluid through the supply tube) and, ultimately, the heat transfer coefficient (HTC) provided by the coolant fluid is higher than would otherwise occur without the increase in velocity. The injection inlets 425 and or the fluid channels thereof are positioned or aligned to target the heat-rejecting surface of the components 405 (e.g., FETs, diodes, or resistors) for jet impingement. As illustrated, the impinged surface is jacketed (by the jacket 415) to maintain high bulk velocities over the entire heat rejection surface and ensure that the entire surface remains fully wetted. The injection point may be located directly over the junction to maximize cooling efficiency.

FIG. 4C illustrates a resulting coolant flow volume 430 surrounding the heat generating components 405 that results from the direct jet impingement via the jacket 415. As illustrated with respect to the cooling system 300 of FIG. 3, after the liquid coolant has been cycled through the cooling jacket 415, the coolant is sumped (e.g., via a sump 320 of FIG. 3) and returned to a pump (e.g., the pump 305 of FIG. 3) for future cycling through the cooling jacket 415. For example, the fluid exits at the perimeter of the component(s) being cooled (e.g., through one or more openings between the jacket 415 and the surface of the PCB 410) and is sumped. This path also provides a secondary benefit by locally cooling a portion of the PCB nearby the heat generating components being cooled.

FIGS. 4D and 4E provide an example of general coolant flow paths 435 through the jacket 415, onto the surface of the FETs 405, and out of the jacket 415 through openings 440 of the overhang portion 426 of the jacket 415 along the surface of the PCB 410. The overhang portion 426 of the jacket 415 overhangs a side surface of the electronic components 405 and includes legs 438 that are coupled to the first surface of the PCB 410 and that partially define the openings 440 (see FIG. 4E). Although the example of FIG. 4A-C illustrates two electronic components 405, in some examples, the system 400 includes one electronic component 405 or more than two electronic components 405. That is, in some examples, the jacket 415 jackets one electronic component 405 and, in other examples, the jacket 415 jackets more than two electronic components 405.

As noted, the cooling devices presented herein can constrain the flow of the fluid to provide a fully wetted device under cooling (e.g., FET 405). In contrast, with an open direct impinging coolant flow, either in the form of a jet or spray, the fluid velocity for a given flow rate is lower and the heat rejection surface does not remain fully wetted, resulting in reduced heat transfer. Limiting the flow volume for a given flow rate, as proposed in some embodiments herein such as with the cooling jackets 415, is counter to traditional design, which typically relies on higher flow rates.

Further, if coolant is freely injected on the device or atomized coolant is sprayed on the device, the HTC that results under such operation is inferior to embodiments disclosed herein. For example, the resulting HTC from such injection or spraying may not be high enough to reject the amount of heat that is desired or needed to maximize power density and efficiency of a system. For instance, in a present study, the HTCs that was needed to reject 60 W/FET was in excess of 3,000 W/m\hat{ }2/K. To approach this HTC, simple spray cooling or direct impingement do not suffice with reasonable flow rates for the system (e.g., 10 L/min for the entire system, in this example) to prevent excessive pumping losses and pressures.

Because flow rates cannot be drastically increased in a real-world system as previously described, embodiments of the cooling systems and methods described herein can reduce the cross-sectional area of the coolant flow so the coolant velocity goes up locally around the device itself while keeping it fully wetted. This is particularly helpful with viscous fluids such as oil or automatic transmission fluid where the limited flow rate is not turbulent and the system is limited to laminated heat transfer, which can be less effective for thermal management. The flow rate required for such fluids to become turbulent would again be very large presenting problematic system efficiencies, as well as prohibitive back pressures. In embodiments of the cooling systems and methods described herein, however, the constrained flow of fluid enables a quasi-tortuous path to be created by directing the flow of the fluid around the corners of a device using the constraining of the flow along with limited flow rates. This provides an elevated HTC locally at the site of cooling, while maintaining reasonable system flow rates and back pressures. By directing the coolant flow around each side of a device under cooling and down to its printed circuit board (PCB), an additional benefit arises by putting fluid on (and cooling) the PCB itself, which has heat and copper traces to cool.

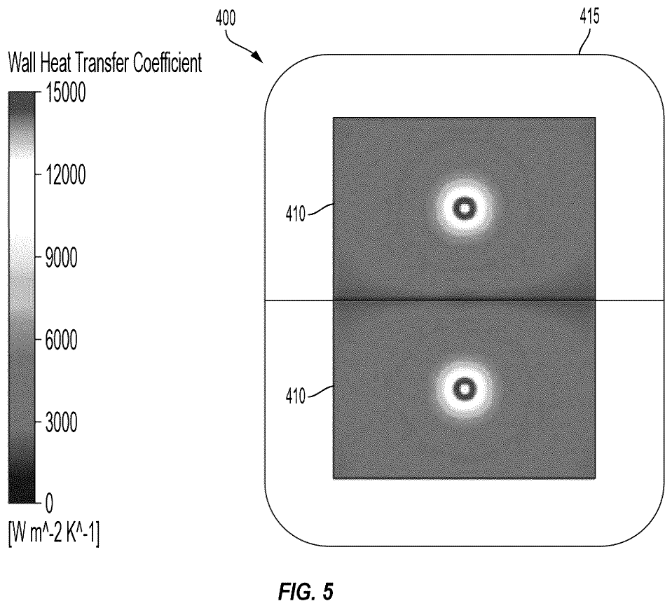

FIG. 5 illustrates an example of heat transfer coefficients for the system 400 due to jacketed direct jet impingement liquid cooling described above.

The cooling provided by embodiments of the cooling systems and methods described herein enable a power electronic device to exceed its rated current by more intensively utilizing a given volumetric flow rate of coolant, resulting in cooler running devices. This cooling also decreases ohmic losses and increases efficiency.

Additionally, while the junction-to-case or junction-to-mount thermal resistance of a power electronic device represents a substantial overhead to cooling of electronic components, in some examples, a caseless junction may be used. In a caseless junction example, the power electronic device may be sintered directly to a high thermal conductivity substrate such as alumina or silicon nitride, which is then liquid cooled on the reverse side, by any of the techniques discussed herein (for example direct jet impingement or jacketed liquid cooling), resulting in lower (in some cases, dramatically lower) junction-to-coolant thermal resistance. For example, in some embodiments of the system 400, the FETs 405 are sintered directly to a high thermal conductivity substrate such as alumina or silicon nitride. The cooling jacket 415 is then positioned on the opposite side of the PCB 410 as the FETs 405, and the coolant fluid is output by the jacket as a stream or jet directly onto the substrate (on the underside or mounting side of the FETs 405).

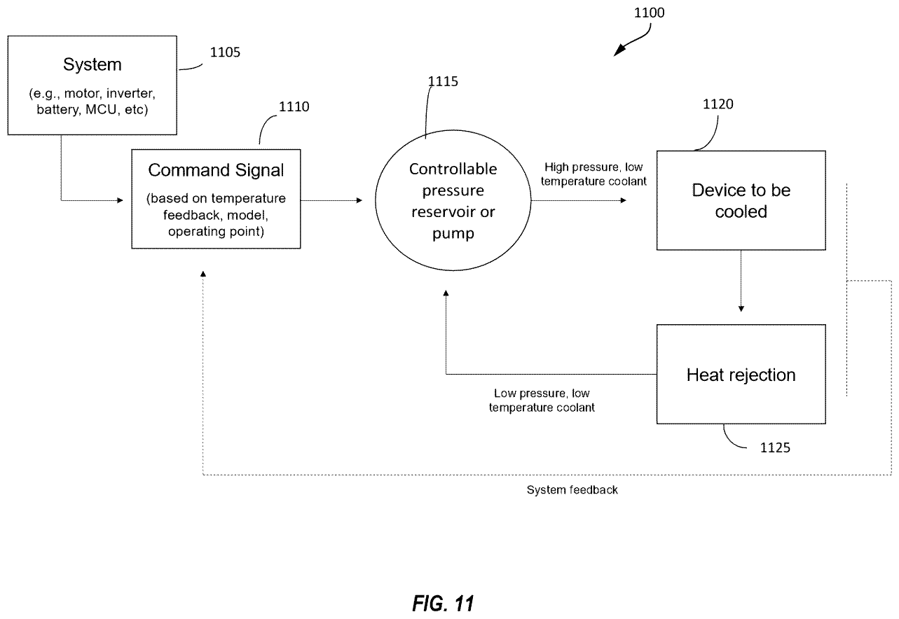

In some examples, a process of managing thermal energy using the cooling jacket 415, or variations thereof, is provided. The process may include receiving a coolant fluid at the inlet 425 formed in the main portion 422. As noted, the coolant fluid may be provided by tubing coupled to the inlet 425. The pump or reservoir, controlled by a controller, may control the flow of coolant fluid through the tubing and to the inlet 425 (see, e.g., FIG. 11 and related discussion below).

The process continues with directing, by the channel 428 coupled to the inlet 425, a jet of the coolant fluid toward the outward surface of the electronic component 405 (see, e.g., fluid along path 435 in FIG. 4D).

The process continues with expelling the coolant fluid out of the cooling jacket via one or more openings 440 in the overhang portion 426 of the cooling jacket 415 (see, e.g., fluid along path 435 in FIG. 4D and openings 440 in FIG. 4E).

In some examples, as noted, a heat sink is coupled to the outward surface of the electronic component 405 (e.g., on a top surface of the electronic component 405 in the view of FIG. 4D). Accordingly, the jet of coolant fluid in these cases impinges a surface of the heat sink. In other examples, a heat sink is not provided. In such cases, the jet of coolant fluid directed by the channel impinges a surface of the electronic component 405.

Similar to the local device designs covered above, an entire system may take advantage of the thermal management systems and methods disclosed herein.

For example, FIG. 6A illustrates an example power converter system 600 with liquid cooling, which may be used in the system 100 in some examples. The system 600 includes a printed circuit board (PCB) 605 with a first surface 606 having mounted thereon electronic components including twelve FETs 610 and three inductors 615. To simplify the diagram, three of the twelve FETs 610 are labeled. With reference to the system 100 of FIG. 1, the FETs 610 may form the power converter 115 of FIG. 1 and the inductors 615 may be a portion of the LC filter 120 of FIG. 1. The electronic components may each have a mounting surface and an outward surface 608 opposite the mounting surface, and the electronic components may be mounted on the first surface 606 of the PCB 605 via the respective mounting surface. Additionally, the first surface 606 of the PCB 605 and the outward surfaces 608 of the plurality of electronic components may form a three-dimensional board surface profile of various elevations.

In the system 600 of FIG. 6A, the power converter formed by the FETs 610 and/or the inductors 615 may be enclosed in a cooling device that directs fluid across the power converter. The cooling device may be injection molded or a 3D printed hard plastic jacket, or shell (see jacket 635 of FIG. 6B) that creates a form fitting tight clearance close to the board 605 and electronic components (e.g., FETs 610 and inductors 615) through which an electrically non-conductive liquid coolant (e.g., oil or transmission fluid) is pumped to reject heat (i.e., cool the power converter). As used herein, a “tight” clearance, fit, or distance may refer to a distance (or space between components) of less than about 1 millimeter (mm), less than 0.75 mm, less than 0.5 mm, less than 0.3 mm, between 0.2 and 1 mm, between 0.2 and 0.75 mm, between 0.2 and 0.5 mm, about 0.25 mm, about 0.5 mm, about 0.75 mm, or about 1 mm. The particular distance of the tight clearance or fit may vary depending on the heat transfer coefficients desired to reject a target amount of heat and the available flow rate and back pressure limitations for a given design. Additionally, the jacket may create a clearance distance between its inner surface and the various electronic components that varies from component to component, or that may be approximately the same for all electronic components. Further, the clearance distance between the inner surface and the PCB surface may be different than the spacing between the inner surface of the jacket and the electronic components, or may be approximately the same. In some examples, the entire inner surface of the jacket or most of the inner surface of the jacket (e.g., more than 50%, more than 60%, more than 70%, more than 80%, more than 90%) may be tightly fitted to the PCB 605 and its electronic components.

Thus, the cooling jacket 635 includes an inner surface with a surface profile that mimics (i.e., generally tracks, follows, or accommodates) the board surface profile (provided by the first surface of the PCB 605 and the outward surfaces of the plurality of electronic components). The jacket 635 may be an example of the jacket 315 of FIG. 3. Similar to other embodiments included herein, the tight clearance maintains high bulk velocity relative to the dissipating surfaces, yielding high heat transfer coefficients for a given flow rate. Additionally, the tight clearance can ensure that the pressurized, viscous coolant flows through all available paths, specifically flowing over dissipating components rather than tending to bypass them as in other cooling systems with a submerged, detached flow. The improved flow of the present embodiments occurs because, for example, the resistance to bypass components is not significantly lower than the resistance to flow over them.

In FIG. 6A, a jacketed coolant volume 620 is shown as a thin layer over one half of the board 605 and its electronic components (with volumes 620 on both top and bottom). Although illustrated as covering half of the board 605 for illustration purposes, the volume 620 may extend over the whole board 605. FIG. 6B illustrates a portion of the system 600 and an example of general coolant flow path 630 providing the jacketed coolant volume 620 a space between a jacket 635 and a surface of the PCB 605 and electronic components 640 (representing, e.g., the FETs 610 and inductors 615). The coolant flow path 630 enters from the left of the diagram at an inlet 645 and exits on the right at outlet 650. Accordingly, the board surface profile and the inner surface of the cooling jacket may form or define a coolant fluid pathway volume 655 through which the coolant fluid may flow along the flow path 630. As shown, the coolant fluid pathway volume may include the inlet 645 at a first end of the cooling jacket 635 and the outlet 650 at a second end of the cooling jacket 635 such that coolant fluid received at the inlet passes over the plurality of electronic components before being output at the outlet. In some examples, the inlet 645 has a cross-sectional area that is substantially smaller (e.g., three, four, five, or more times smaller) than the cross-sectional area of a supply tube providing the liquid coolant to the cooling jacket 415. Here, the cross-sectional area refers to the surface area of an imaginary two-dimensional plane that is perpendicular to the flow of the coolant fluid. Accordingly, the inlet 645 narrows the fluid flow space such that the fluid flow velocity through the coolant flow path 630 is increased (relative to the velocity of the fluid through the supply tube) and, ultimately, the heat transfer coefficient (HTC) provided by the coolant fluid to the components 640 and PCB 605 is higher than would otherwise occur without the increase in velocity.

The diagram of FIG. 6B illustrates the jacket 635 on only the top-side of the PCB 605. In some examples, as shown in FIG. 6C, the jacket 635 is formed by 3D printed “clamshells” sandwiching the board and its components with tight clearance, and through which pressurized coolant is pumped. That is, the jacket 635 may be replicated on the opposite (bottom) side of the PCB 605 as well (as bottom-side jacket 660), such that heat rejection (cooling) may happen from both sides of the board, top and bottom, in these examples. The bottom-side jacket forms an additional (bottom-side) flow path 665. Although not illustrated in FIG. 6C, in some examples, additional electronic components are also mounted on the bottom side of the PCB. The bottom-side jacket 660 may have a similarly tight clearance with respect to the bottom surface and any electronic components thereon.

FIG. 6D illustrates the system 600 with an example of the jacket 635 that provides the jacketed coolant volume 620, the coolant flow path 630, and the coolant flow path 665. FIG. 6E shows a cutaway view of the system 600 of FIG. 6D. The jacket 635 includes an inlet 670 aligned with an orifice 675 in the PCB 605. The coolant fluid enters the inlet 670 and a portion of the fluid passes over the top surface of the PCB 605 (e.g., similar to coolant flow path 630) and a portion of the fluid passes under the bottom surface of the PCB 605 (similar to the coolant flow path 665). The coolant fluid flows across the components 610, 615 to provide cooling, and then exits through an outlet of the jacket 635 (not shown), which may be similar in form to the inlet 670 but located, e.g., at a far end (opposite the inlet 665) of the jacket 635 and, in some examples, on the underside of the PCB 605 and bottom portion of the jacket 635. In some examples, the orifice 675 and the bottom portion of the jacket 635 are not provided, similar to the illustration of FIG. 6B.

Generally, coolant flow should be maintained such that it is stable for a given system, such as the system 600.

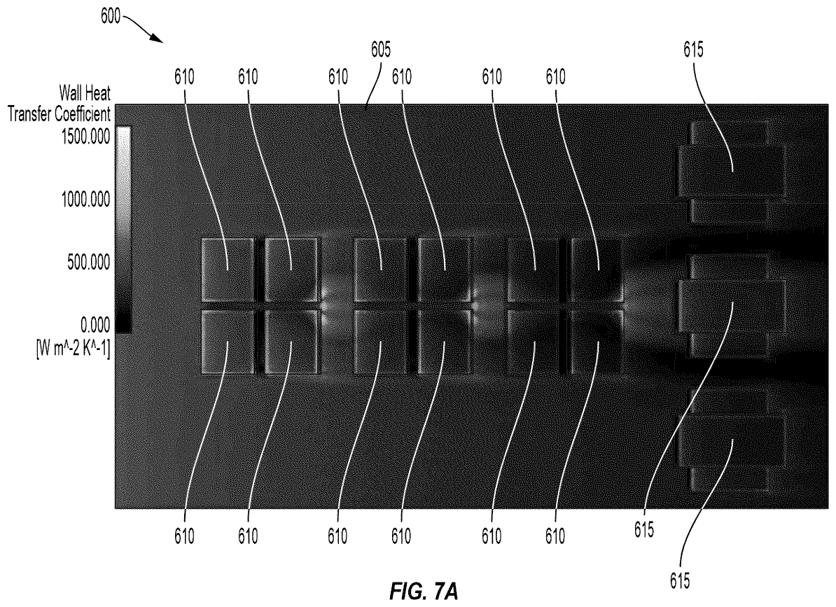

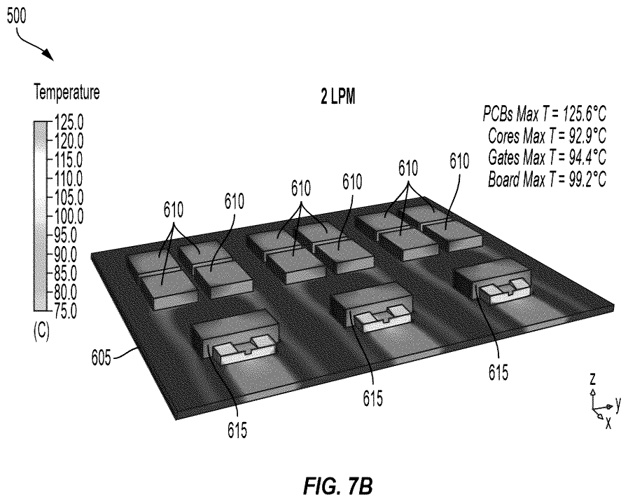

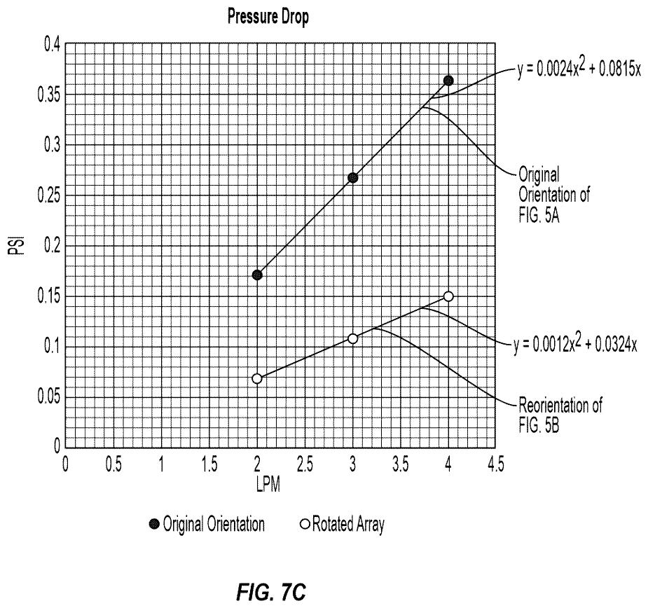

FIG. 7A illustrates an example of heat rejection or transfer from the PCB 605, FETs 610, and inductors 615 resulting from the jacketed liquid cooling as illustrated in FIGS. 6A and 6B, injected from the left.

The orientation of the geometry may be varied within the context of the cooling device to vary the heat management results. For example, in the system of FIG. 7A, the gate array in a single double-wide file upstream of the center inductor has two potentially adverse effects. First, the heat generated by the 60 W of power from the twelve FETs 610 is picked up by the central streamlines of cooling, leading the middle inductor 615 to see warmer coolant than the other two inductors 615. Second, the coolant travels the full length of the board through the 1 mm jacket, experiencing substantial pressure drop.

Substantial improvements may be seen through reorientation of the system. For example, rotating the array of FETs 610 by 90° and shortening the distance of the board over which the coolant fluid flows can reduce the experienced pressure drop and the inductor component temperatures. FIG. 7B shows an example of this reoriented system 700 and its corresponding heat transfer profile. This reoriented system 700 includes the FETs 610 and inductors 615 rearranged on the PCB 605, but is otherwise similar to the system 600 of FIGS. 6A-B and FIG. 7A (i.e., with jacket (not shown), etc.). Thus, in FIG. 7B, the PCB, which is generally rectangular in shape, has a length and a width, where the length is greater than the width. The jacket has the inlet(s) and outlet(s) on opposite sides of the width of the PCB and, accordingly, the coolant fluid flows from inlet to outlet in the direction along the width of PCB, which is a shorter distance than if the coolant fluid flowed from inlet to outlet along the length of the PCB (as shown in FIG. 7A). As shown in the example of FIG. 7B, the peak temperature of the FETs 610 has dropped 0.8° C.

FIG. 7C shows a graph that plots pressure drop vs. flow rate for the two orientations. Notably, the static drop for the rotated orientation (system 700 of FIG. 7B) is 60% lower than that of the original orientation (system 600 of FIG. 7A). The linearity of the loss curves indicates that the loss is dominated by viscous rather than inertial forces-hence limiting the total stream length through the cooling jacket benefits the loss for a given flow rate and design.

In some examples of the above-described systems, rather than directly liquid cooling the thermal rejection surface of a given component, which limits the surface area available for heat rejection, the component may be coupled (e.g., soldered or mechanically clamped) to a high thermal conductivity heat sink, which is then itself directly liquid cooled. The heat sink may be a traditional finned or pin heat sink, or it may simply be a high conductivity material used either for the inverter board itself or as a local wafer onto which the component is mounted, and the reverse side (i.e. opposite to the side on which the dissipating component is mounted) may be cooled by jacketed or jet impingement liquid cooling or a combination thereof.

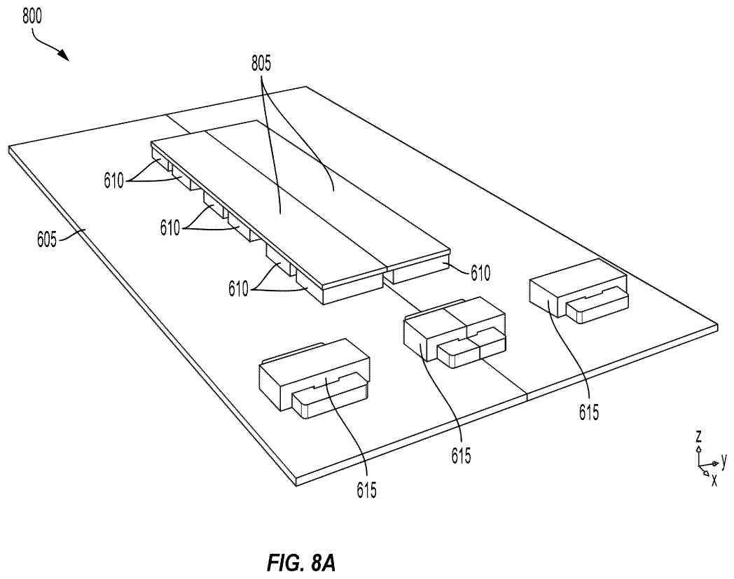

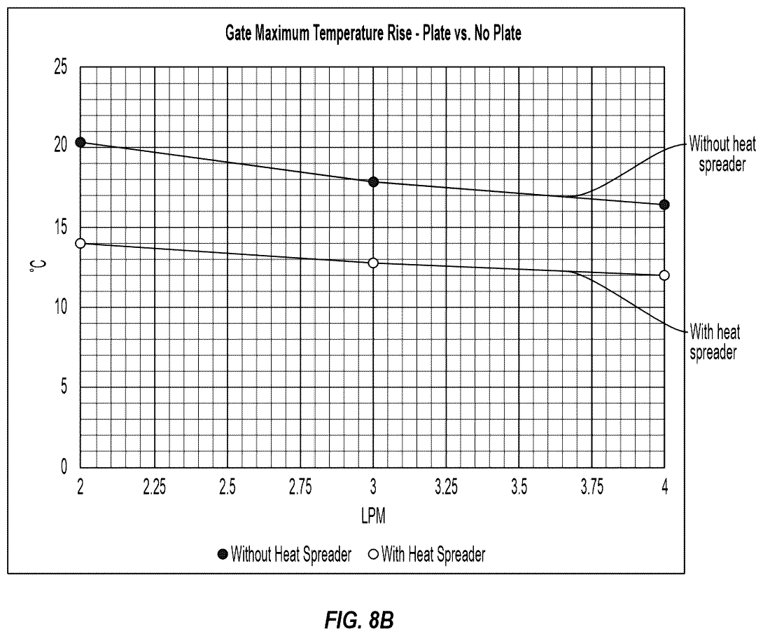

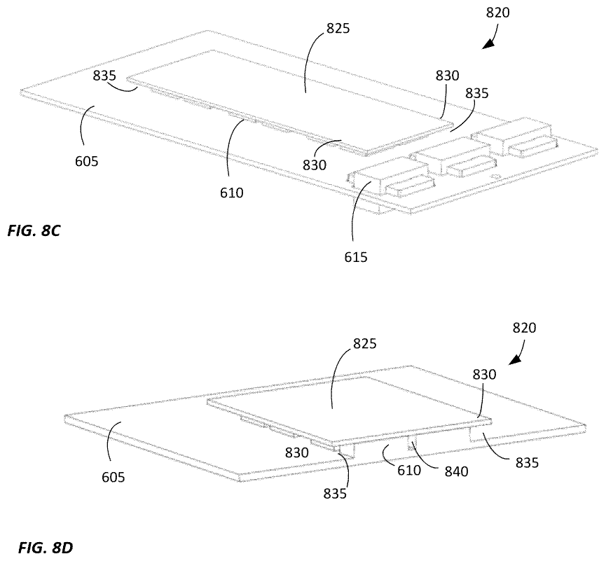

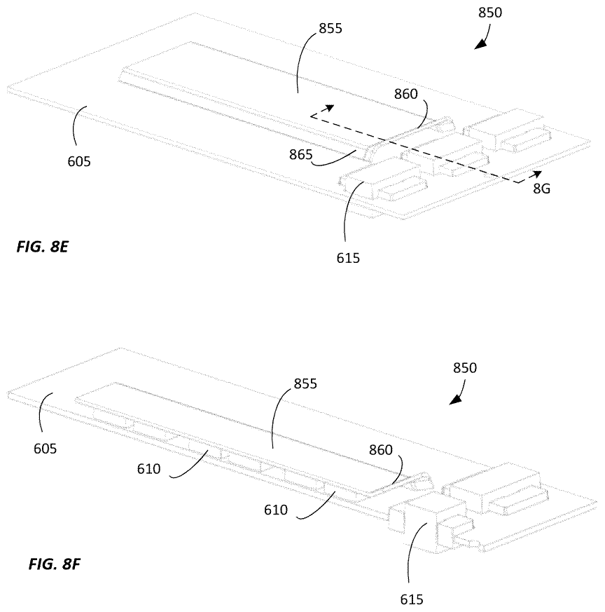

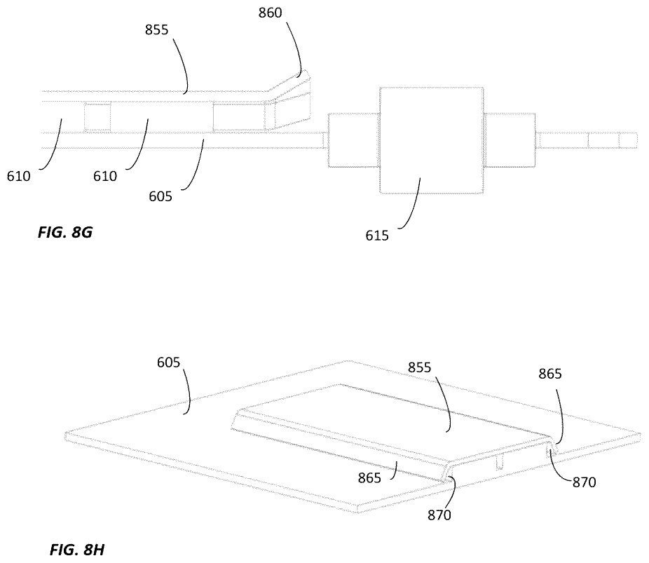

For example, FIG. 8A illustrates a system 800 with devices under cooling (e.g., FETs 610) that may be soldered or mechanically clamped to an aluminum plate 805. More specifically, in the particular example, a first set of six FETs 10 are coupled to a first plate 805 and a second set of six FETS 610, which mirror the first set of six FETs 610, are coupled to a second plate 805. The design of the plates 805 may vary from traditional heat sink designs, which require high surface area to mass (typically requiring finned or pinned structures) and, hence, increase volume (and thereby decrease power density). In a particular example of the system 800, the plate 805 was relatively thin (only 1.5 mm thick), limiting additional volume, and was placed in contact with the top surface of the FETs 610. The outer boundary of the plate 805 was coincident with the outer bounding box of the FETs 610 (i.e., there was no overhang of the plate beyond the gates).

This example of FIG. 8A demonstrates that a heat spreader having simple mechanical configuration, such as plate 805, can provide substantial improvement (i.e., reduction) in the temperatures of the power electronics or gates (e.g., the FETs 610). As shown in FIG. 8B, the peak temperature rise in the gates was reduced by ~4-6° C., depending on flow rate. Improvement was larger at lower flow rate. At only 2.55 LPM, the peak gate temperature rise dropped from 18.8° C. without the spreader to 13.2° C. with it, an improvement of 5.6° C. without the addition of much thermal mass or volumetric space.

In other embodiments, an overhang of the plate 805 may be used to create a second coolant channel between the top surface of the board and underside of the overhang of the plate 805. For example, in FIG. 8C a system 820 is provided with a plate 825 having an overhang 830 providing second cooling channels 835. FIG. 8D provides a cutaway view of the system 820 of FIG. 8C, which more clearly illustrates the second cooling channels 835, as well as a central cooling channel 840 (that is also present in the system 800 of FIG. 8A). The system 820 and the plate 825 are similar to the system 800 and plate 805 (including having six FETs 610 and three inductors 615), except for the overhang 830 and resulting second coolant channels 835. These second channels 835 increase the cooling surface area and can lower the temperatures (increase cooling action) by providing additional interaction with the fluid, as well as additional velocity of the fluid within the system. This second channel may also create a subsystem within the system. The subsystem may be a thermal management system embedded within the primary thermal management system wherein fluid is directly managed, and discrete velocities are thereby imposed. Such velocities may be actively controlled, for instance by a pump in some embodiments, while others may be passively controlled, for instance by the device itself. Further, there may be local and global velocities predicated on the device layout. Further, this allows for active cooling to be maintained on both sides of the heat spreader, which is counter to traditional heat sinks that are typically limited to a single side of passive or active cooling. The local flow rate necessary for a given heat rejection (e.g., as determined by an operating condition, duration, trajectory, or direct feedback from a sensor) may by estimated by the controller 105 which maintains a global flow that enables such local operation. Such estimation can be performed offline (e.g., using a lookup table, or the like) or online (e.g., solving in real time) either through a proportional-integral-derivative type controller, or a model-predictive type controller.

In other embodiments, a heat sink plate may include a flared inlet collector and/or side skirt. For example, in FIGS. 8E-8H, a system 850 is provided with a plate 855 having a flared inlet collector 860 and side skirt 865, resulting in second cooling channels 870. FIG. 8F provides a cutaway view of the system 850 of FIG. 8E, FIG. 8G provides a partial cross-sectional view of the system 850 of FIG. 8E along its length, and FIG. 8H provide another cutaway view of the system 850 of FIG. 8E. The system 850 and the plate 855 are similar to the system 800 and plate 805 (including having six FETs 610 and three inductors 615), except for the flared inlet collector 860, side skirt 865, and second cooling channels 870. The flared inlet collector 860 may direct coolant fluid passing over the PCB 605 into the second channels 870. Further, because of the narrow passages of the second channels 870 compared to an opening of the flared inlet collector 860, the coolant fluid velocity may increase in the channels 870 to increase the heat transfer.

In some embodiments, the heat spreader 805, 825, and/or 855 of FIGS. 8A and 8C, respectively, take(s) another form, such as having a finned or pinned structure.

In some examples of the above-described systems in which heat sinks are incorporated, the heat sinks may further be mechanically clamped to Thermal-Electric Coolers (TECs), which are then liquid cooled (e.g., similar to the manner in which heat-generating components or their associated heat sinks are liquid-cooled as being above). In some examples, TECs can reach a ΔT of up to 60° C. below ambient, which can provide additional cooling capabilities.

For the device and methods discussed herein, flow may be described as local to a specific region of the device, or global across the system or a subsystem thereof. For example, an embodiment with local and global flow was previously described with respect to the heat spreader of FIG. 8A modified to include an overhang. Another embodiment with local and global flow may be described in the context of a gapped PCB structure. This gapped PCB structure may be used to implement a multilevel inverter, or another power conversion device such as an inductor. For certain embodiments, such as an inductor, this design configuration is counter intuitive as traditional design would try to maximize copper fill to minimize resistive losses. However, embodiments discussed herein using gapped coils or PCBs may sacrifice copper for thermal management capability (e.g., to flow fluid between the levels of conductors), which may benefit both packaging (e.g., size) and performance (e.g., efficiency) constraints. Further, the gapped PCB structure may enable use of a smaller optimized inductor for a certain lower power region, while maintaining the capability of higher power operation given the thermal headroom afforded by the thermal management system. This is counter to traditional designs, which typically have to be sized to peak operational constraints.

In some examples, inductors with a gapped PCB structure are provided that have multiple stacked PCBs with turns (i.e., coil turns located on or embedded as traces of the respective PCBs), also referred to as a gapped PCB inductor. The gapped PCB inductor includes gaps between the respective PCBs of the stack to provide coolant flow paths between the PCBs. These flow paths allow direct cooling of both faces of the PCBs.

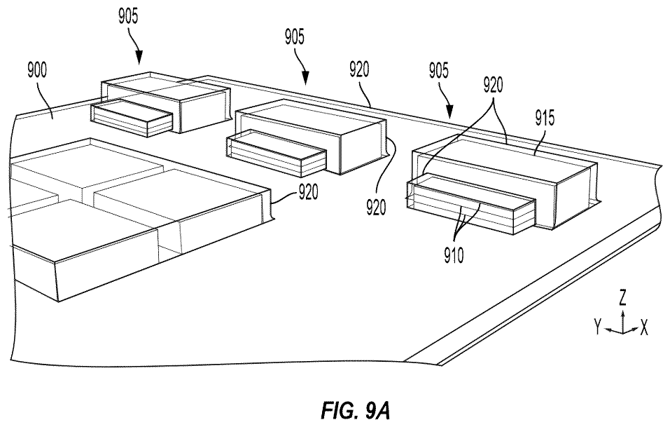

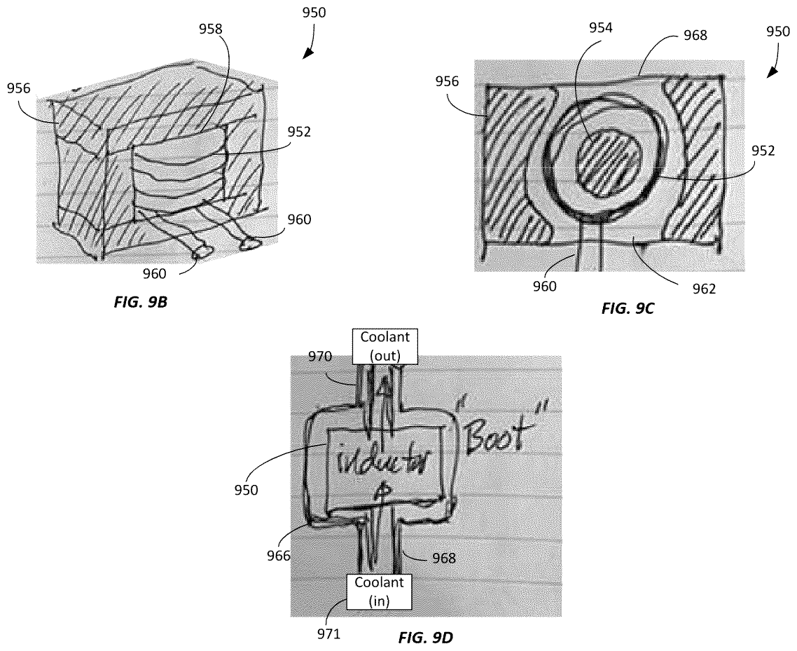

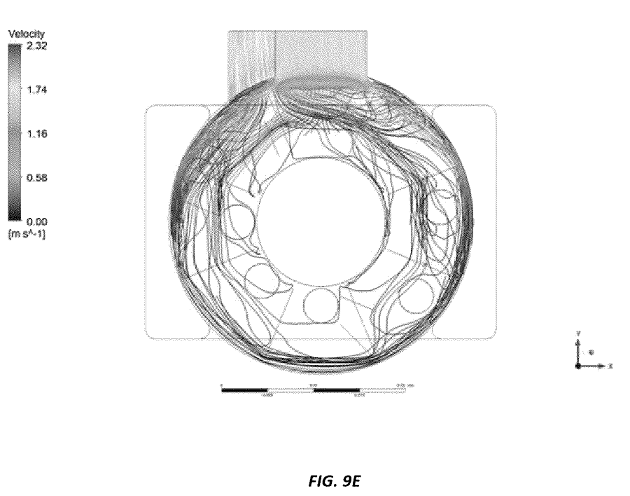

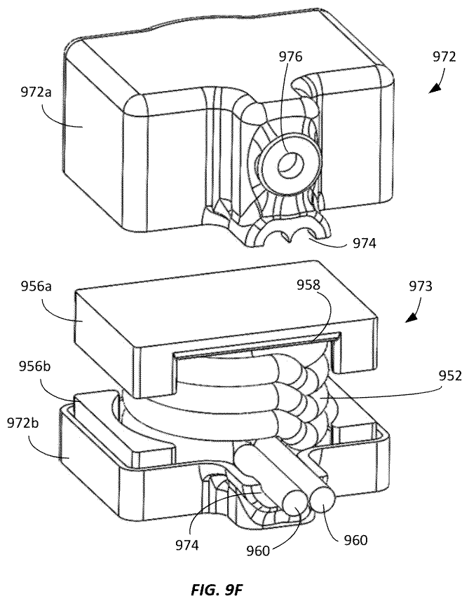

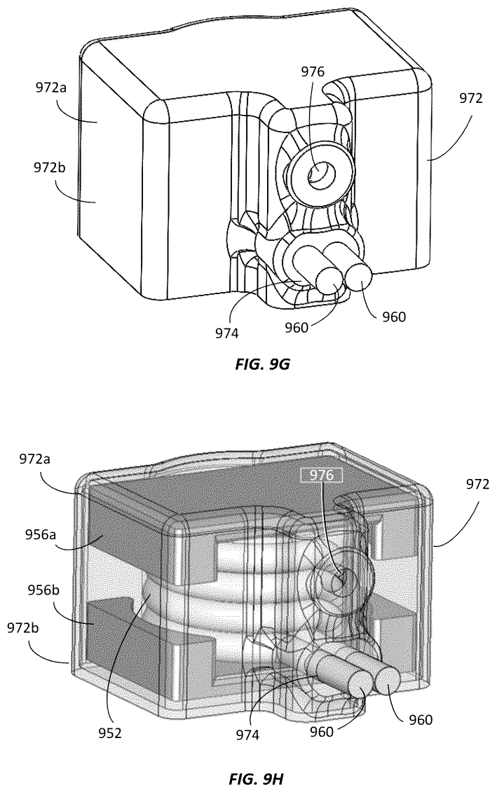

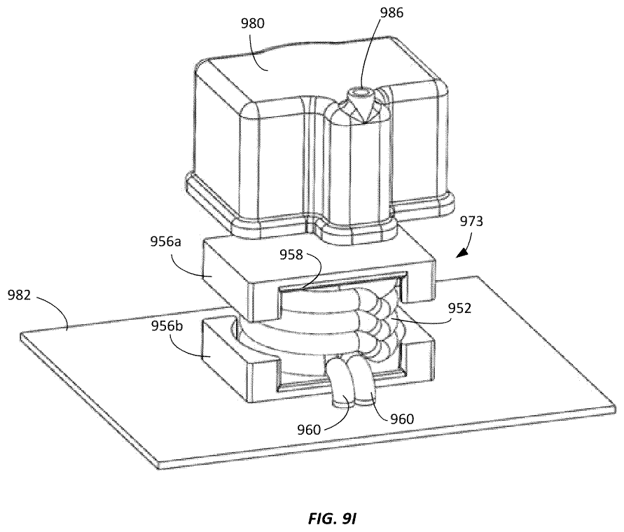

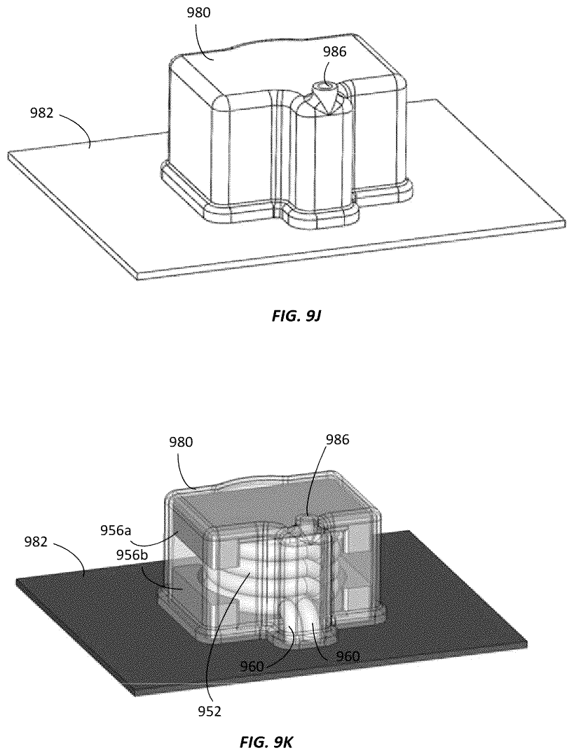

FIG. 9A illustrates a portion of a printed circuit board (PCB) 900 including three gapped PCB inductors 905. Aside from the inductors 905, the PCB 900 may be otherwise similar to the PCB 605, including having similar components as the PCB 605 (e.g., components 610) and used within a power converter system (e.g., the system 100) in a similar manner as the PCB 605. The gapped PCB inductors 905 are illustrated as having a coil portion including three PCBs 910, each with at least one turn, and a core portion 915. The core portion 915 may include two portions or halves on opposite sides of the PCBs 910, thereby sandwiching the PCBs 910. In FIG. 9A, a first portion (top half) of the core portion 915 is illustrated. On an underside of the board, a second portion (bottom half) of the core portion 915, similar in form to the first portion, is provided. In some examples, the core portion 915 includes a center leg extending through the coil turns (e.g., each. In other examples, the core portion 915 does not include a center leg and the coil turns have an air core (neglecting any PCB material that may be present within the radii of the coil turns).

In some of these examples, each gapped PCB inductors 905, or a plurality of the gapped PCB inductors 905, is placed within a duct or jacket such that coolant is squeezed between all PCBs of the PCB gapped PCB inductors(s) 905. The duct, or jacket, may be tightly fitted to the gapped PCB inductors 905, similar to the jackets described herein (e.g., jackets 315, 635, 415, 660, etc.), and/or similar to jacket 966 of FIG. 9D, jacket 972 of FIGS. 9F-9H, or jacket 980 of FIGS. 9I-9K, described further below. Thus, as illustrated in FIG. 9A, a jacketed coolant volume 920, similar to jacketed coolant volume 620 of FIG. 6, provides a coolant flowing across the electrical components on the PCB 900.

FIGS. 9B-C illustrate an inductor 950, which is another example of the inductor 615. The inductor 950 includes a copper coil or winding 952 wound around a center ferrite core portion 954 and within an outer core portion 956. The inductor 950 may be, for example, a “PQ” style inductor with a litz style winding. In other examples, the inductor 950 is an inductor of another type and/or includes a non-litz style copper winding.

Additionally, the inductor 950 includes a window 958 defined by the core and exposing the winding 952. The inductor 950 further includes terminals 960 at opposite ends of the winding 952. As discussed with respect to FIG. 9D, the window 958 includes an inlet 962 and an outlet 964 through which coolant fluid flows.

FIG. 9D illustrates a boot 966 jacketing the inductor 950. The boot 966 includes a coolant inlet 968 and a coolant outlet 970. The boot 966 directs a flow of coolant fluid 971 through the inductor 950 to cool the inductor 950. More particularly, in operation, a supply of coolant fluid is provided to the coolant inlet 968 (e.g., via tubing), which flows through the window inlet 962 of the inductor 950, across the winding 952, out through the window outlet 964, and out through the coolant outlet 970. For example, the boot 966 may abut the outer core portion 956 such that the coolant fluid is forced through the window 958 of the inductor 950. In some examples, the boot is sized slightly larger to provide a gap between the boot 966 and the outer surface of the outer core portion 956. In such examples, the coolant fluid may also flow around, above, and/or under the inductor 950 to provide additional surface area in contact with the coolant fluid and increase heat transfer through the coolant fluid.

FIG. 9E illustrates a fluid flow velocity diagram for the boot 966 and inductor 950 example of FIG. 9D.

FIG. 9F illustrates, in an exploded view, a clamshell boot 972, which is an example of the boot 966 of FIG. 9D, with an inductor 973, which is an example of the inductor 950. The inductor 973 has similar components as the inductor 950 that are similarly labeled, except that the core of the inductor 973 is separated into a top portion 956a and bottom portion 956b. The clamshell boot 972 includes a top portion 972a and a bottom portion 972b. FIGS. 9G and 9H illustrate the clamshell boot 970 with the top portion 972a and bottom portion 972b joined or adhered together, with FIG. 9H illustrating the boot 972 partially transparent. The clam shell portions 972a and 972b may be adhered to one another via ultrasonic welding, adhesive, or other technique. In some examples, the top portion 972a and the bottom portion 972b have approximately the same height and may be referred to as halves. In other examples, the heights of the portions vary. The clamshell boot 970 may further include a lead port 974 through which the leads 960 of the inductor 970 can pass. The lead port 974, as illustrated, is formed at the interface of the top and bottom portions 972a, 972b of the clamshell boot 972. Additionally, welding can seal the inductor leads 960 to the boot 972. The clamshell boot 972 further includes a fluid inlet 976 (an example of the inlet 968 of FIG. 9D) in the top portion 956a and a fluid outlet (an example of the outlet 970 and similar to the fluid inlet 974 in form) in the bottom portion 956b on the opposite side (i.e., backside not shown) of the clamshell boot 972. Accordingly, the fluid inlet 976 may be in a top center of the boot 972 above the lead inlet 974, while the fluid outlet is in the back lower half, which can force the coolant fluid 971 (see FIG. 9D) to traverse the inductor 973 both top to bottom and front to back.

FIG. 9I illustrates, in an exploded view, a board-sealed boot 980, which is another example of the boot 966 of FIG. 9D, with the inductor 973, which, as previously noted, is an example of the inductor 950 of FIG. 9D. The board-sealed boot 980 may be formed as a unitary or single-piece component and sealed to a printed circuit board (PCB) 982 on which the inductor 973 is mounted. FIGS. 9J and 9K illustrate the board-sealed boot 980 sealed to the PCB 982, with FIG. 9K illustrating the boot 980 partially transparent. The PCB 982 may be an example of or a portion of the PCB 605 or 900, described above. The inductor leads 960 are connected to traces in the PCB 982, avoiding an orifice through which to pass the leads 960 out of boot 980. The boot 980 further includes a fluid inlet 986 (an example of the inlet 968 of FIG. 9D) near or at a top and front of the boot 980, and a fluid outlet (an example of the outlet 970 and similar to the fluid inlet 974 in form) near or at a bottom and opposite side (i.e., backside not shown) of the boot 980. Accordingly, the fluid inlet 986 may be in a top center of the boot 980, while the fluid outlet is in the back lower half, which can force the coolant fluid 971 (see FIG. 9D) to traverse the inductor 973 both top to bottom and front to back. In some examples, one or both of the inlet 986 and outlet may include orifices in the PCB 982 to connect a volume defined by the boot 980 to an inflow and/or outflow of the coolant fluid 971 below the PCB 982. In other examples, one or both of the inlet 986 or outlet are positioned elsewhere on the boot 980.

In some examples, the inductor 950 (e.g., in the form of inductor 970 or as a gapped inductor 905) with the boot 966 (e.g., in the form of boot 972 or 980), as shown in FIG. 9D-9K, may be an example of the inductor 615 or gapped PCB inductor 905, and the boot 966 may be integrated into (or a portion of) a jacket similar to the jacket 635 covering two or more electrical components and a PCB (see FIGS. 6A-6C). In some examples, two or more boots 966 (e.g., in the form of boot 972 or 980), each jacketing a respective inductor 950 or 970, are coupled in series, such that an outlet 970 of a first boot 966 is linked to an inlet 968 of a second boot 966. In some examples, two or more boots 966 (e.g., in the form of boot 972 or 980), each jacketing a respective inductor 950 or 970, are coupled in parallel, such that an inlet 968 of a first boot 966 and an inlet 968 of a second boot 966 are coupled to the same source of coolant fluid and an outlet 970 of the first boot 966 and the second boot 966 are coupled as well.

In some examples, the inlets 968, 976, and/or 986 have a diameter that is substantially smaller (e.g., three, four, five, or more times smaller) than the diameter of a supply tube providing the liquid coolant to the boot 966, 972, 980. In other words, the cross-sectional area of the inlets 968, 976, and/or 986 is smaller than the cross-sectional area of the supply tube, where the cross-sectional areas refer to the surface areas of imaginary two-dimensional planes that are perpendicular to the flow of the coolant fluid. Accordingly, the inlets 968, 976, and/or 986 narrow the fluid flow space such that the fluid flow velocity through the inlet is increased (relative to the velocity of the fluid through the supply tube) and, ultimately, the heat transfer coefficient (HTC) for the inductor 950, 970 provided by the coolant fluid is higher than would otherwise occur without the increase in velocity.

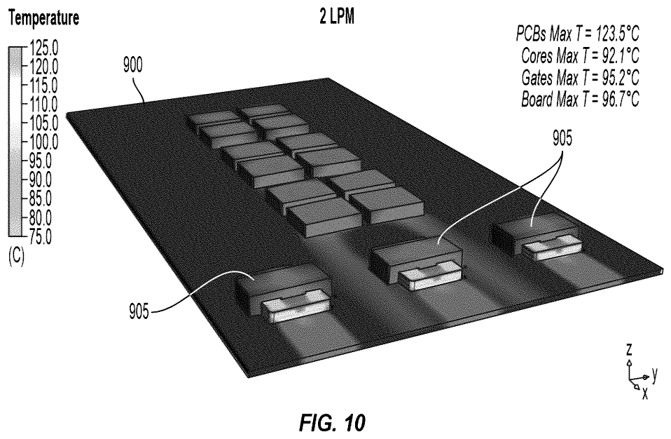

FIG. 10 illustrates heat transfer coefficients for the PCB 900 including gapped PCB inductors 905 due to ducted liquid coolant flow as described with respect to FIG. 9A.

In some examples, a process of managing thermal energy using the cooling jacket 635 (see FIG. 6B), or variations thereof, is provided. The process may include receiving a coolant fluid at the inlet 645 of the coolant fluid pathway volume 655 defined by the inner surface of a cooling jacket 635 and a board surface profile formed by a first surface 606 of a printed circuit board 605 and outward surfaces 608 of a plurality of electronic components 640 of the printed circuit board. As noted, the inner surface has a surface profile that mimics the board surface profile. In some examples, a pump or reservoir, controlled by a controller, may control the flow of coolant fluid to the inlet 645 (see, e.g., FIG. 11 and related discussion below).

The process continues with cooling the plurality of electronic components 640 via the coolant fluid traveling through the coolant fluid pathway volume 655 along coolant flow path 630.

The process continues with outputting the coolant fluid from the outlet 650 of the coolant fluid pathway volume 655.

In some examples of the process, the board surface profile is further formed by an outward surface of heat sink that is coupled to a further electronic component of the printed circuit board, as shown in, for example, FIG. 8A.

In some examples of the process, a controller (e.g., controller 105 of FIG. 1) determines a temperature of the plurality of electronic components based on a sensor output (e.g., a temperature sensor of the sensor(s) 140). In response, the controller controls a coolant pump (e.g., coolant pump 305) that controls a flow of the coolant fluid through the coolant fluid pathway volume based on the temperature. For example, generally, as temperature increases, the controller may increase the flow of coolant fluid. Similarly, as temperature decreases, the controller may decrease the flow of coolant fluid through the coolant fluid pathway volume.

In various embodiments disclosed herein, coolant fluid in the system may be actively or passively controlled, both locally and across the system (or subsystem). This control may be done through a single pump, or set of pumps, in addition to local topological variations. See, for example, FIG. 3 and the description thereof. FIG. 11 also illustrates a control diagram 1100 for some embodiments provided herein. The control diagram 1100 includes a system 1105, a command signal 1110, a controllable pressure reservoir or pump 1115, a device to be cooled 1120, and heat rejection 1125. In some examples, the system 1105 may represent the components of the system 100 other than the cooling system 155, and the other components of diagram of FIG. 11 may represent the cooling system 155 (or features, functions, and related components thereof).

In some examples, the system 1105 illustrated in FIG. 11 may include a motor, inverter, battery, sensor(s), and/or a microcontroller. The system 1105 (e.g., the microcontroller) transmits a command signal 1110 to a controllable pressure reservoir or a pump 1115 based on temperature feedback (e.g., from a temperature sensor), operating point of the system, and/or a model of the system. The reservoir or pump is then controlled, base don't he command signal 1110, to control a high pressure, low temperature coolant to flow to the device 1120. The device 1120 is then cooled via the high pressure and low temperature coolant. The coolant carries away heat (heat rejection 1125) as low pressure, low temperature coolant back to the reservoir or pump 1115. System feedback (e.g., temperature feedback, pressure feedback, etc.) may further be provided to the system 1105 and/or command signal 1110 to adjust control of the reservoir or pump 1115 and, ultimately, control the cooling action if the device 1120.

The embodiments described herein may also include variable flow embodiments that are tied to the operational capability or output of the power conversion device, or system it is embedded in. For instance, in the context of a traction inverter for driving a traction motor, higher power operation from a motor control of the traction motor may prompt a higher flow rate through the cooling device and system used to cool the traction inverter. The cooling system may implement a minimum fluid flow requirement such that cooling system does not allow air to be induced in the system. In some embodiments, there may be a variable speed positive displacement system that uses a separate pump as the main fluid loop, or the same pump. In some embodiments, the cooling system includes a higher pressure (coolant fluid) source and uses an adjustable valve that may turn the higher-pressure source on or off, as desired. For instance, the cooling system may include a supplemental fluidic circuit with the higher-pressure source that can be tapped into by the coolant system for additional (or reduced) coolant flow, wherein the valve controls whether the supplemental fluidic circuit is used and, ultimately, the pressure of the coolant flow.

As noted above, by providing cooling using the above techniques, power density of a power converter can be increased. In an example, a six-FET power converter with and without a heat sink and using air cooling was evaluated. For the evaluation, the maximum dissipation can be calculated given the thermal resistance of the components. The thermal resistance between the FET junction and case R_{θJC} is 0.45° C./Watt (W), the thermal pad R_{θP} is 0.25° C./W, and the heatsink R_{θH} is 173° C./W. In this example, all six FETs share a common heatsink and the heat effectively travels through the parallel combination of six FETs and thermal pads in series with the heatsink, resulting in the following equation:

$${P}_{diss} = \frac{{T}_{J , m ax} - {T}_{a}}{\frac{1}{6} ( {R}_{θ JC} + {R}_{θ P} ) + {R}_{θ H}}$$

For a maximum allowable FET junction temperature T_{J,max} of 150° and an ambient air temperature Tₐ of 60° C., the maximum tolerable total FET loss is 310 W, roughly 50 W per FET. Here, the maximum allowable output current of this inverter is 15 Amperes (A) per phase, well below the capabilities of the FET, which represents 12.47 kW in total and a power density of 6.74 kW/L. This result implies that the limit on maximum power for this converter lies within the heatsink and improving the heatsink will result in increased power density and output power.

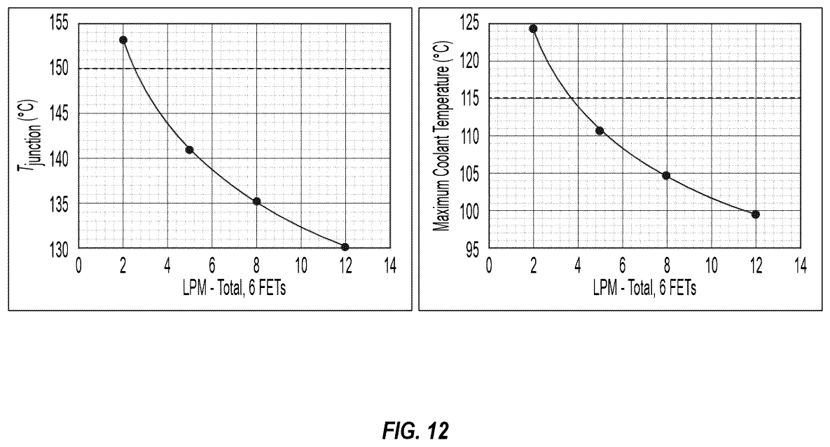

However, with direct contact jet impingement cooling (e.g., as described with respect to FIGS. 4A-E), the limiting factor for power output can be improved, resulting in increased output power and power density. In an example, the datasheet-specified value for junction-to-case thermal resistance R_{θJC}=0.45° C./W was used to calculate an effective bulk thermal conductivity for the FET bodies such that the temperature difference developed across each FET at 60 W is 27° C., with the heat load applied at the base of the FET body; hence, the temperature that develops there is the junction temperature. The thermal contact between the bottom of the FET and the board is disallowed, as well as between the perimeter of the FET and the coolant so that essentially all heat is rejected from the upper surface by liquid cooling. The inlet coolant temperature is assumed to be 75° C., a reasonable value for automotive applications. The jacket clearance and injection port diameter were varied to determine values that are capable of rejecting 60 W per FET in steady state for a reasonable oil flow (e.g., less that 4 LPM for the entirety of the six FETs), and for a reasonable total pressure (e.g., less than 20 psi). The maximum allowable junction temperature is assumed to be 150° C., and the maximum allowable ATF temperature is assumed to be 115° C. In light of these requirements, values of the jacket clearance and injection port ID of 0.25 mm and 1 mm, respectively, were selected. As can be seen in FIG. 12, which illustrates graphs of junction temperature and maximum coolant temperature versus flow rate for the design, this results in a minimum flow rate required to keep the junction temperature below 150° C. of only 2.5 LPM (total for all 6 FETs), but a minimum flow rate of 3.7 LPM, or 0.63 LPM/FET, is required to keep the maximum coolant temperature below 115° C. The mass-flow averaged coolant temperature rise at the outlet for this flow rate is then 3.3° C., while the total heat required at the inlet is 12.9 PSI. The average heat transfer coefficient over the FET is ≈3900 Wm⁻²K⁻¹, weighted toward the region of jet impingement. These results demonstrate that direct contact ATF jet impingement cooling offers improved performance over the air-cooled solution.

The present disclosure has described one or more embodiments, and it should be appreciated that many equivalents, alternatives, variations, and modifications, aside from those expressly stated, are possible and within the scope of the application. Features of the disclosed embodiments can be combined, rearranged, etc., within the scope of the application to provide additional embodiments.

### FURTHER EXAMPLES

Example 1: A method, apparatus, and/or non-transitory computer-readable medium storing processor-executable instructions for a non-isolated power converter system comprising: a printed circuit board having a first surface; a plurality of electronic components of the printed circuit board, each having an outward surface, the first surface and outward surfaces of the plurality of electronic components forming a board surface profile; a cooling jacket coupled to the printed circuit board, the cooling jacket having an inner surface, the inner surface having a surface profile that mimics the board surface profile; and a coolant fluid pathway volume defined by the board surface profile and the inner surface of the cooling jacket.

Example 2: The method, apparatus, and/or non-transitory computer-readable medium of Example 1, wherein the plurality of electronic components includes at least one electronic component mounted on the first surface of the printed circuit board via a mounting surface that is opposite the outward surface.

Example 3: The method, apparatus, and/or non-transitory computer-readable medium of Example 1 or 2, wherein the plurality of electronic components includes at least one integrated electronic component that is integrated into the printed circuit board, the integrated electronic component occupying a first component area of the printed circuit board corresponding to a portion of the first surface of the printed circuit board, wherein the cooling jacket covers the portion of the first surface such that coolant fluid received at an inlet of the coolant fluid pathway volume passes over the integrated electronic component before being output at an outlet.

Example 4: The method, apparatus, and/or non-transitory computer-readable medium of any of Examples 1 to 3, wherein the integrated electronic component is a gapped printed circuit board (PCB) inductor, and the integrated electronic component includes at least one coil turn embedded in each of a plurality of printed circuit boards (PCBs) of the gapped PCB inductor.

Example 5: The method, apparatus, and/or non-transitory computer-readable medium of Example 4, wherein the inductor is placed within a duct portion of the cooling jacket such that the coolant fluid is squeezed between the plurality of PCBs.

Example 6: The method, apparatus, and/or non-transitory computer-readable medium of any of Examples 1 to 5, further comprising a heat sink coupled to the outward surfaces of at least two electronic components of the plurality of electronic components, the heat sink forming a portion of the board surface profile such that coolant fluid received at an inlet passes over the heat sink before being output at an outlet.

Example 7: The method, apparatus, and/or non-transitory computer-readable medium of any of Examples 1 to 6, wherein the inner surface of the cooling jacket includes a clearance with respect to the outward surfaces of the plurality of electronic components of between 0.2 millimeters and 1.0 millimeters.

Example 8: The method, apparatus, and/or non-transitory computer-readable medium of any of Examples 1 to 7, wherein the coolant fluid pathway volume includes an inlet at a first end of the cooling jacket and an outlet at a second end of the cooling jacket such that coolant fluid received at the inlet passes over the plurality of electronic components before being output at the outlet.

Example 9: The method, apparatus, and/or non-transitory computer-readable medium of Example 8, wherein the inlet has a cross sectional area through which the coolant fluid flows that is smaller than a cross-sectional area of a supply tube that provides the coolant fluid to the inlet.

Example 10: A method, apparatus, and/or non-transitory computer-readable medium storing processor-executable instructions for a non-isolated power converter system comprising: a printed circuit board having a first surface; at least one electronic component of the printed circuit board, each of the at least one electronic component having an outward surface; and a cooling jacket having a main portion covering the outward surface of the at least one electronic component, an injection inlet formed in the main portion, the injection inlet configured to receive a coolant fluid into the cooling jacket and to direct a jet of the coolant fluid toward the outward surface of the at least one electronic component, and an overhang portion overhanging a side surface of the at least one electronic component, the overhang portion including an opening between the cooling jacket and the first surface of the printed circuit board that provides an exit out of the cooling jacket for the coolant fluid directed toward the outward surface.

Example 11: The method, apparatus, and/or non-transitory computer-readable medium of Example 10, wherein at least one of the at least one electronic component has a mounting surface opposite the outward surface and is mounted on the first surface of the printed circuit board via the mounting surface.

Example 12: The method, apparatus, and/or non-transitory computer-readable medium of any of Examples 10 to 11, wherein at least one of the at least one electronic component is an integrated electronic component that is integrated into the printed circuit board, the integrated electronic component occupying a first component area of the printed circuit board including a portion of the first surface of the printed circuit board.

Example 13: The method, apparatus, and/or non-transitory computer-readable medium of Example 12, wherein the integrated electronic component is an inductor or gapped PCB inductor, and the integrated electronic component includes at least one coil turn embedded in the printed circuit board.

Example 14: The method, apparatus, and/or non-transitory computer-readable medium of any of Examples 10 to 13, wherein the at least one electronic component includes a single electronic component and the cooling jacket covers the single electronic component.

Example 15: The method, apparatus, and/or non-transitory computer-readable medium of any of Examples 10 to 14, wherein the at least one electronic component includes a first electronic component and a second electronic component, wherein the injection inlet is a first injection inlet to direct the jet of the coolant fluid toward the outward surface of the first electronic component, and wherein the main portion further comprises a second injection inlet configured to receive further coolant fluid into the cooling jacket and to direct a second jet of the further coolant fluid toward the outward surface of the second electronic component.

Example 16: The method, apparatus, and/or non-transitory computer-readable medium of any of Examples 10 to 15, wherein the injection inlet has channel through which the coolant fluid passes to form the jet of the coolant fluid, wherein the channel has a cross-sectional area through which the coolant fluid flows that is smaller than a cross-sectional area of a supply tube that provides the coolant fluid to the inlet.

1. A thermal management system for a power converter comprising:
a printed circuit board having a first surface;
a plurality of electronic components of the printed circuit board, each having an outward surface, the first surface and outward surfaces of the plurality of electronic components forming a board surface profile;
a cooling jacket coupled to the printed circuit board, the cooling jacket having an inner surface, the inner surface having a surface profile that mimics the board surface profile; and
a coolant fluid pathway volume defined by the board surface profile and the inner surface of the cooling jacket.

2. The thermal management system of claim 1, wherein the plurality of electronic components includes at least one electronic component mounted on the first surface of the printed circuit board via a mounting surface that is opposite the outward surface.

3. The thermal management system of claim 1,
wherein the plurality of electronic components includes at least one integrated electronic component that is integrated into the printed circuit board, the integrated electronic component occupying a first component area of the printed circuit board corresponding to a portion of the first surface of the printed circuit board,
wherein the cooling jacket covers the portion of the first surface such that coolant fluid received at an inlet of the coolant fluid pathway volume passes over the integrated electronic component before being output at an outlet.

4. The thermal management system of claim 3, wherein the integrated electronic component is a gapped printed circuit board (PCB) inductor, and the integrated electronic component includes at least one coil turn embedded in each of a plurality of printed circuit boards (PCBs) of the gapped PCB inductor.

5. The thermal management system of claim 4, wherein the inductor is placed within a duct portion of the cooling jacket such that the coolant fluid is squeezed between the plurality of PCBs.

6. The thermal management system of claim 1, further comprising a heat sink coupled to the outward surfaces of at least two electronic components of the plurality of electronic components, the heat sink forming a portion of the board surface profile such that coolant fluid received at an inlet passes over the heat sink before being output at an outlet.

7. The thermal management system of claim 1, wherein the inner surface of the cooling jacket includes a clearance with respect to the outward surfaces of the plurality of electronic components of between 0.2 millimeters and 1.0 millimeters.

8. The thermal management system of claim 1, wherein the coolant fluid pathway volume includes an inlet at a first end of the cooling jacket and an outlet at a second end of the cooling jacket such that coolant fluid received at the inlet passes over the plurality of electronic components before being output at the outlet.

9. The thermal management system of claim 8, wherein the inlet has a cross sectional area through which the coolant fluid flows that is smaller than a cross-sectional area of a supply tube that provides the coolant fluid to the inlet.

10. A thermal management system for a power device comprising:
a printed circuit board having a first surface;
at least one electronic component of the printed circuit board, each of the at least one electronic component having an outward surface; and
a cooling jacket having
a main portion covering the outward surface of the at least one electronic component,
an injection inlet formed in the main portion, the injection inlet configured to receive a coolant fluid into the cooling jacket and to direct a jet of the coolant fluid toward the outward surface of the at least one electronic component, and
an overhang portion overhanging a side surface of the at least one electronic component, the overhang portion including an opening between the cooling jacket and the first surface of the printed circuit board that provides an exit out of the cooling jacket for the coolant fluid directed toward the outward surface.

11. The thermal management system of claim 10, wherein at least one of the at least one electronic component has a mounting surface opposite the outward surface and is mounted on the first surface of the printed circuit board via the mounting surface.

12. The thermal management system of claim 10, wherein at least one of the at least one electronic component is an integrated electronic component that is integrated into the printed circuit board, the integrated electronic component occupying a first component area of the printed circuit board including a portion of the first surface of the printed circuit board.

13. The thermal management system of claim 12, wherein the integrated electronic component is an inductor or gapped PCB inductor, and the integrated electronic component includes at least one coil turn embedded in the printed circuit board.

14. The thermal management system of claim 10, wherein the at least one electronic component includes a single electronic component and the cooling jacket covers the single electronic component.

15. The thermal management system of claim 10, wherein the at least one electronic component includes a first electronic component and a second electronic component, wherein the injection inlet is a first injection inlet to direct the jet of the coolant fluid toward the outward surface of the first electronic component, and
wherein the main portion further comprises a second injection inlet configured to receive further coolant fluid into the cooling jacket and to direct a second jet of the further coolant fluid toward the outward surface of the second electronic component.

16. The thermal management system of claim 10, wherein the injection inlet has channel through which the coolant fluid passes to form the jet of the coolant fluid, wherein the channel has a cross-sectional area through which the coolant fluid flows that is smaller than a cross-sectional area of a supply tube that provides the coolant fluid to the inlet.

17. A method of managing thermal energy, the method comprising:
receiving a coolant fluid at an inlet of a coolant fluid pathway volume defined by an inner surface of a cooling jacket and a board surface profile, the board surface profile formed by a first surface of a printed circuit board and outward surfaces of a plurality of electronic components of the printed circuit board and the inner surface having a surface profile that mimics the board surface profile;
cooling a plurality of electronic components via the coolant fluid traveling through the coolant fluid pathway volume; and
outputting the coolant fluid from an outlet of the coolant fluid pathway volume.

18. The method of managing heat of claim 17, wherein the board surface profile is further formed by an outward surface of heat sink that is coupled to a further electronic component of the printed circuit board.

19. The method of managing heat of claim 17, further comprising:
determining, by a controller, a temperature of the plurality of electronic components based on a sensor output; and
controlling, by the controller, a coolant pump that controls a flow of the coolant fluid through the coolant fluid pathway volume based on the temperature.

20. A method of managing thermal energy, the method comprising:
receiving a coolant fluid at an inlet formed in a main portion of cooling jacket, the main portion covering an outward surface of an electronic component on a first surface of a printed circuit board;
directing, by a channel coupled to the inlet, a jet of the coolant fluid toward the outward surface of the electronic component; and
expelling the coolant fluid out of the cooling jacket via an opening in an overhang portion of the cooling jacket, the opening being between the cooling jacket and the first surface of the printed circuit board.

21. The method of managing heat of claim 20, wherein a heat sink is coupled to the outward surface of the electronic component, and wherein the jet of coolant fluid directed by the channel impinges a surface of the heat sink.

22. The method of managing heat of claim 20, wherein the electronic component is a field effect transistor, and wherein the jet of coolant fluid directed by the channel impinges a surface of the field effect transistor.
